(19) United States
(12) Patent Application Publication
(10) Pub. No.: US 2023/0232669 A1
(43) Pub. Date: Jul. 20, 2023

(54) DISPLAY DEVICE AND METHOD OF MANUFACTURING THE DISPLAY DEVICE

(71) Applicant: Samsung Display Co., Ltd., Yongin-si (KR)

(72) Inventors: Kyungmin Kim, Yongin-si (KR); Junhyeong Park, Yongin-si (KR); Dongwon Kim, Yongin-si (KR)

(21) Appl. No.: 18/154,696

(22) Filed: Jan. 13, 2023

(30) Foreign Application Priority Data
Jan. 14, 2022 (KR) 10-2022-0006173

(51) Int. Cl. H10K 59/124; H10K 59/12; H10K 59/80; H10K 59/60; H01L 31/054

(52) U.S. Cl. CPC H10K 59/124; H10K 59/1201; H10K 59/8731; H10K 59/60; H01L 31/0547; H10K 59/8791; H10K 59/353

(57) ABSTRACT

A display device and a method of manufacturing the display device are provided. The display device includes a substrate including a transmissive display area including a first pixel area, a second pixel area, and an opening area between the first pixel area and the second pixel area and defining a substrate opening portion, a light-emitting element layer above the substrate and including a first light-emitting element in the first pixel area and a second light-emitting element in the second pixel area, and a first inorganic encapsulation layer above the light-emitting element layer and extending from the first pixel area to the second pixel area across the substrate opening portion.

### CROSS-REFERENCE TO RELATED APPLICATION

This application claims priority to, and the benefit of, Korean Patent Application No. 10-2022-0006173, filed on Jan. 14, 2022, in the Korean Intellectual Property Office, the disclosure of which is incorporated by reference herein in its entirety.

### BACKGROUND

### 1. Field

One or more embodiments relate to a display device and a method of manufacturing the display device.

### 2. Description of the Related Art

Recently, display devices have been diversified in use. In addition, as the display devices are becoming thinner and lighter, the range of use of the display devices is further increasing.

Various functions for connecting or linking to a display device have been increased while enlarging the area occupied by the display area of the display device. As a method to add various functions while enlarging the area, a display device having an area that performs various functions while displaying an image has been studied.

### SUMMARY

One or more embodiments include a display device and a method of manufacturing the display device, wherein the display device includes a transmissive display area having high light transmittance or sound transmittance to perform various functions while displaying an image.

Additional aspects will be set forth in part in the description that follows and, in part, will be apparent from the description, or may be learned by practice of the presented embodiments of the disclosure.

According to one or more embodiments, a display device includes a substrate including a transmissive display area including a first pixel area, a second pixel area, and an opening area between the first pixel area and the second pixel area and defining a substrate opening portion, a light-emitting element layer above the substrate and including a first light-emitting element in the first pixel area and a second light-emitting element in the second pixel area, and a first inorganic encapsulation layer above the light-emitting element layer and extending from the first pixel area to the second pixel area across the substrate opening portion.

The display device may further include an organic encapsulation layer above the first inorganic encapsulation layer and including a first organic encapsulation portion overlapping the first light-emitting element in a plan view, a second organic encapsulation portion overlapping the second light-emitting element in the plan view, and a third organic encapsulation portion overlapping the substrate opening portion in a plan view and extending between the first light-emitting element and the second light-emitting element, and a second inorganic encapsulation layer above the organic encapsulation layer.

The first organic encapsulation portion, the second organic encapsulation portion, and the third organic encapsulation portion may be integrally provided.

The display device may further include an inorganic insulating layer between the substrate and the light-emitting element layer, defining an inorganic insulating layer opening portion overlapping the substrate opening portion in a plan view, and directly contacting the first inorganic encapsulation layer, and an organic insulating layer between the inorganic insulating layer and the light-emitting element layer and defining an organic insulating layer opening portion overlapping the substrate opening portion in a plan view, a width of the organic insulating layer opening portion being greater than a width of the inorganic insulating layer opening portion.

The display device may further include an organic encapsulation layer above the first inorganic encapsulation layer and having at least a portion in the inorganic insulating layer opening portion and the organic insulating layer opening portion, and a second inorganic encapsulation layer above the organic encapsulation layer.

The display device may further include an inorganic layer between the organic insulating layer and the light-emitting element layer, defining an inorganic layer opening portion overlapping the substrate opening portion in a plan view, and having at least a portion of a lower surface thereof in direct contact with the first inorganic encapsulation layer, the lower surface facing the substrate.

The substrate may include an organic substrate layer defining an organic substrate opening portion as part of the substrate opening portion, and an inorganic substrate layer above the organic substrate layer and defining an inorganic substrate opening portion as part of the substrate opening portion, wherein a width of the organic substrate opening portion is greater than a width of the inorganic substrate opening portion, and wherein the first inorganic encapsulation layer is in direct contact with at least a portion of a lower surface of the inorganic substrate layer, the lower surface facing the organic substrate layer.

The light-emitting element layer may include a first pixel electrode in the first pixel area, a first emission layer above the first pixel electrode, a second pixel electrode in the second pixel area, a second emission layer above the second pixel electrode, and an opposite electrode above the first emission layer and the second emission layer and defining an opposite electrode opening portion overlapping the substrate opening portion in a plan view.

The light-emitting element layer may further include a first functional layer between the first pixel electrode and the first emission layer and defining a first functional layer opening portion overlapping the substrate opening portion in a plan view, a second functional layer between the first emission layer and the opposite electrode and defining a second functional layer opening portion overlapping the substrate opening portion in a plan view, and a capping layer above the opposite electrode and defining a capping layer opening portion overlapping the substrate opening portion in a plan view.

The display device may further include a protective layer below the substrate, overlapping the opening area in a plan view, and including at least one of glass, an organic protective layer including an organic material, and an inorganic protective layer including an inorganic material.

The display device may further include a component overlapping the first pixel area, the opening area, and the second pixel area in a plan view.

The substrate may further include a display area surrounding at least a portion of the transmissive display area, wherein the light-emitting element layer further includes a third light-emitting element in the display area.

The opening area may include a plurality of opening areas in the transmissive display area, the plurality of opening areas including first opening areas spaced apart from one another along a virtual first straight line extending in a first direction, and second opening areas spaced apart from one another along a virtual second straight line parallel to the virtual first straight line, wherein a virtual third straight line that is between adjacent ones of the first opening areas, and that extends in a second direction crossing the first direction, passes through a center of one of the second opening areas.

The display device may further include an anti-reflection layer above the first inorganic encapsulation layer and including a first circular polarization layer, a light reflection layer below the substrate, and a light compensation layer between the substrate and the light reflection layer and including a second circular polarization layer.

The display device may further include a solar cell layer below the substrate.

According to one or more embodiments, a method of manufacturing a display device includes forming a substrate and a display substrate above a support substrate, the substrate including a first pixel area, a second pixel area, and a middle area between the first pixel area and the second pixel area, and the display substrate including a first pixel electrode in the first pixel area and a second pixel electrode in the second pixel area, forming an opening area defining a substrate opening portion exposing at least a portion of an upper surface of the support substrate by removing at least a portion of the substrate from the middle area, forming a first emission layer above the first pixel electrode, a second emission layer above the second pixel electrode, an opposite electrode above the first emission layer and the second emission layer, and a capping layer above the opposite electrode, forming a first inorganic encapsulation layer above the capping layer and extending from the first pixel area to the second pixel area across the substrate opening portion, and separating the substrate from the support substrate.

The method may further include forming, above the first inorganic encapsulation layer, an organic encapsulation layer including a first organic encapsulation portion overlapping the first pixel area in a plan view, a second organic encapsulation portion overlapping the second pixel area in a plan view, and a third organic encapsulation portion overlapping the substrate opening portion in a plan view and extending between the first pixel electrode and the second pixel electrode, and forming a second inorganic encapsulation layer above the organic encapsulation layer, wherein the first inorganic encapsulation layer continuously extends across the first pixel area, the opening area, and the second pixel area.

The substrate may include an organic substrate layer, and an inorganic substrate layer above the organic substrate layer, and defining an inorganic substrate opening portion overlapping the middle area in a plan view, wherein the forming of the opening area includes forming an organic substrate opening portion having a width that is greater than a width of the inorganic substrate opening portion in the organic substrate layer.

The forming of the opposite electrode and the capping layer may include forming a portion of the opposite electrode and a portion of the capping layer above an upper surface of the support substrate, the upper surface being exposed by the substrate opening portion, wherein the forming of the first inorganic encapsulation layer includes forming the first inorganic encapsulation layer above the portion of the capping layer in the opening area, and wherein the separating of the substrate from the support substrate includes separating the portion of the first inorganic encapsulation layer and the portion of the capping layer from each other in the opening area when the substrate is separated from the support substrate.

The forming of the opening area may include forming an etch protection layer above the first pixel electrode and the second pixel electrode, the etch protection layer defining an etch protection layer opening portion overlapping the middle area in a plan view in the etch protection layer, etching at least a portion of the substrate in the middle area, and removing the etch protection layer.

### BRIEF DESCRIPTION OF THE DRAWINGS

The above and other aspects of embodiments of the disclosure will be more apparent from the following description taken in conjunction with the accompanying drawings, in which:

FIG. 1A is a schematic perspective view of a display device according to one or more embodiments;

FIG. 1B is a schematic perspective view of a display device according to one or more other embodiments;

FIG. 2 is a cross-sectional view schematically illustrating the display device taken along the line A-A′ of FIG. 1B ;

FIG. 3 is a schematic plan view of a display panel according to one or more embodiments;

FIG. 4 is an equivalent circuit diagram schematically illustrating a pixel of a display device;

FIG. 5 is a plan view schematically illustrating a transmissive display area of a display panel according to one or more embodiments;

FIG. 6 is a plan view schematically illustrating a transmissive display area and a display area of a display panel according to one or more embodiments;

FIGS. 7A and 7B are cross-sectional views each schematically illustrating the display panel taken along the line B-B′ of FIG. 5, according to one or more embodiments;

FIGS. 8A to 8I are cross-sectional views schematically illustrating a method of manufacturing a display device according to one or more embodiments;

FIG. 9 shows an experimental result showing a portion of a first inorganic encapsulation layer in an opening area and a pixel area;

FIGS. 10A to 10C are cross-sectional views each schematically illustrating the display panel taken along the line B-B′ of FIG. 5, according to one or more other embodiments;

FIG. 11 is a schematic perspective view of a display device according to one or more other embodiments;

FIG. 12 is a cross-sectional view schematically illustrating the display device taken along the line C-C′ of FIG. 11, according to one or more embodiments;

FIG. 13 is a cross-sectional view schematically illustrating the display device taken along the line C-C′ of FIG. 11, according to one or more embodiments; and

FIG. 14 is a cross-sectional view schematically illustrating the display device taken along the line C-C′ of FIG. 11, according to one or more other embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

A display device is a device for displaying an image, and may include a portable mobile device, such as a game machine, a multimedia device, and a micro personal computer. The display device to be described below may include a liquid-crystal display device, an electrophoretic display device, an organic light-emitting display device, an inorganic light-emitting display device, a field emission display device, a surface-conduction electron-emitter display device, a quantum dot display device, a plasma display device, a cathode ray display device, or the like. Hereinafter, although an organic light-emitting display device is described as an example of the display device according to one or more embodiments, various types of display devices stated above may be used in one or more embodiments.

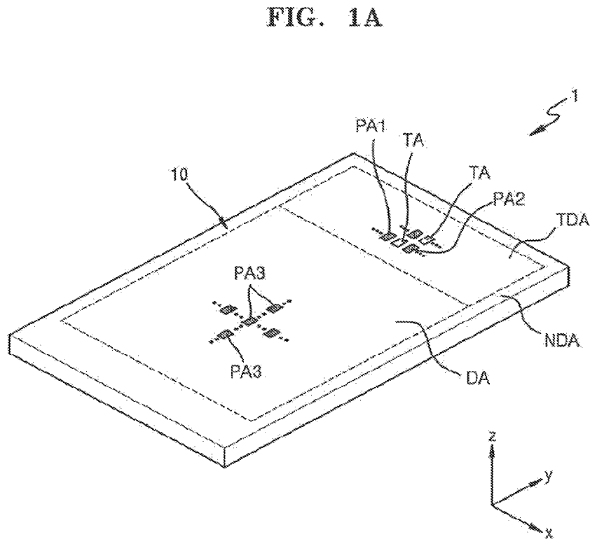

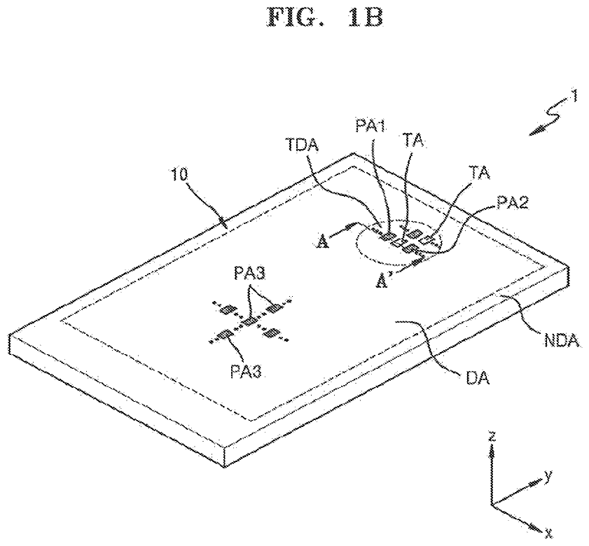

FIG. 1A is a schematic perspective view of a display device 1 according to one or more embodiments. FIG. 1B is a schematic perspective view of the display device 1 according to one or more other embodiments.

Referring to FIG. 1A, the display device 1 may include a display panel 10. The display panel 10 may include a transmissive display area TDA, a display area DA, and a non-display area NDA.

The display device 1 may display an image in the transmissive display area TDA. In one or more embodiments, a component may be located below the transmissive display area TDA. As to be described below, the component may be located below the display panel 10, and may be a sensor or a camera using infrared light, visible light, or sound. The light transmittance or sound transmittance of the transmissive display area TDA may be greater than the light transmittance or sound transmittance of the display area DA. The transmissive display area TDA may include a first pixel area PA1, a second pixel area PA2, and a transmission area TA. Each of the first pixel area PA1 and the second pixel area PA2 may be provided in plurality. A respective light-emitting element may be arranged in each of the first pixel area PA1 and the second pixel area PA2. In one or more embodiments, one light-emitting element may be arranged in each of the first pixel area PA1 and the second pixel area PA2. In one or more other embodiments, a plurality of light-emitting elements may be arranged in each of the first pixel area PA1 and the second pixel area PA2. The transmission area TA may be between the first pixel area PA1 and the second pixel area PA2. The light transmittance or sound transmittance of the transmission area TA may be greater than the light transmittance or sound transmittance of the first pixel area PA1 or the light transmittance or sound transmittance of the second pixel area PA2. A plurality of transmission areas TA may be provided.

The display area DA may surround at least a portion of the transmissive display area TDA. In other words, the display area DA may be adjacent to the transmissive display area TDA. Although FIG. 1A illustrates that the transmissive display area TDA is arranged on one side of the display area DA in a bar type, in one or more other embodiments, the transmissive display area TDA may also be arranged on one side of the display area DA in a notch type. In one or more other embodiments, the transmissive display area TDA may be variously arranged in the display area DA.

The display device 1 may display an image in the display area DA. The display area DA may include a third pixel area PA3. A plurality of third pixel areas PA3 may be arranged in the display area DA. In one or more embodiments, one light-emitting element may be arranged in the third pixel area PA3. In one or more other embodiments, a plurality of light-emitting elements may be arranged in the third pixel area PA3.

The display device 1 may display a first image in the transmissive display area TDA, and may display a second image in the display area DA. In this case, the first image and the second image may each be a respective portion of any one image provided by the display device 1.

The display device 1 may not display an image in the non-display area NDA. The non-display area NDA may be adjacent to the transmissive display area TDA and/or the display area DA. In one or more embodiments, the non-display area NDA may entirely surround the transmissive display area TDA and/or the display area DA in plan view. A driver or the like, which may be configured to provide electrical signals or power to a light-emitting element, may be arranged in the non-display area NDA. The non-display area NDA may include a pad area to which an electronic device, a printed circuit board, or the like may be electrically connected.

Referring to FIG. 1B, the transmissive display area TDA may be entirely surrounded by the display area DA. In one or more embodiments, the transmissive display area TDA may have a circular shape or an elliptical shape in a plan view. In one or more other embodiments, the transmissive display area TDA may have a polygonal shape such as a rectangular shape or the like in a plan view. In addition, the position and/or number of transmissive display areas TDA may also be variously changed. For example, the display panel 10 may include a plurality of transmissive display areas TDA.

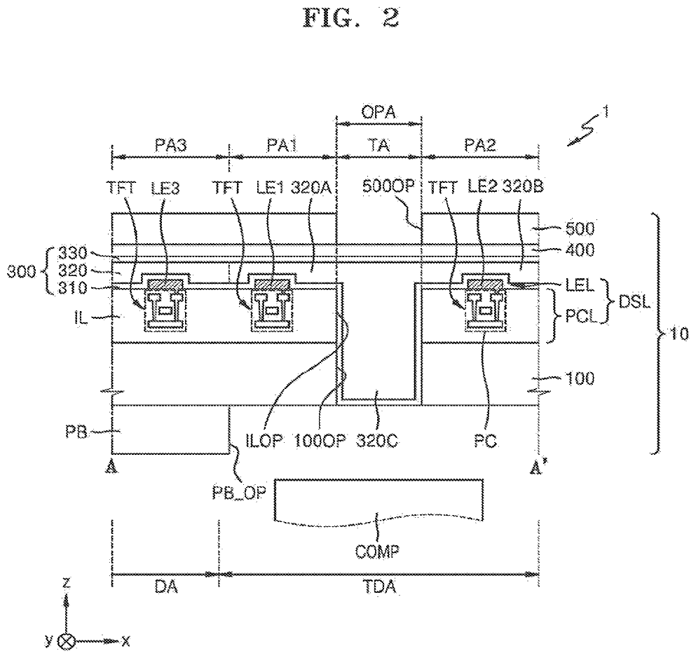

FIG. 2 is a cross-sectional view schematically illustrating the display device 1 taken along the line A-A′ of FIG. 1B.

Referring to FIG. 2, the display device 1 may include the display panel 10 and a component COMP. The display panel 10 may include a substrate 100, a display layer DSL, an encapsulation layer 300, a touch sensor layer 400, an anti-reflection layer 500, and a lower protective film PB. The display layer DSL, the encapsulation layer 300, the touch sensor layer 400, and the anti-reflection layer 500 may be located on (e.g., above) the substrate 100. The lower protective film PB may be located below the substrate 100.

Areas of the display panel 10 may be defined in the substrate 100 and/or a multi-layered film. For example, the display area DA and the transmissive display area TDA may be defined in the substrate 100. In other words, the substrate 100 may include the display area DA and the transmissive display area TDA. The transmissive display area TDA may include the first pixel area PA1, the second pixel area PA2, and the transmission area TA. The display area DA may include the third pixel area PA3.

The transmission area TA may be between the first pixel area PA1 and the second pixel area PA2. The transmission area TA may include an opening area OPA having a substrate opening portion 100OP. The opening area OPA may be an area without the substrate 100. In other words, the opening area OPA may be an area in which the substrate opening portion 100OP is arranged or defined. As described above, because the transmission area TA includes the opening area OPA, the light transmittance or sound transmittance of the display panel 10 may be increased.

In one or more embodiments, the substrate 100 may include glass. In one or more other embodiments, the substrate 100 may include a polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. In one or more embodiments, the substrate 100 may have a multi-layered structure including a base layer including the polymer resin described above, and a barrier layer. The substrate 100 including the polymer resin may be flexible, rollable, or bendable.

The display layer DSL may be located on the substrate 100. The display layer DSL may include a pixel circuit layer PCL and a light-emitting element layer LEL. The pixel circuit layer PCL may include an insulating layer IL and a pixel circuit PC. The insulating layer IL may be located on the substrate 100. The insulating layer IL may include an inorganic material and/or an organic material. The insulating layer IL may include (e.g., define) an insulating layer opening ILOP overlapping the substrate opening portion 100OP in a plan view. The insulating layer opening ILOP may be connected to the substrate opening portion 100OP. Accordingly, the light transmittance or sound transmittance of the display panel 10 may be increased in the opening area OPA. The pixel circuit PC may be inserted into the insulating layer IL. The pixel circuit PC may include at least one transistor TFT. In one or more embodiments, a plurality of pixel circuits PC may be included. The plurality of pixel circuits PC may be arranged in the first pixel area PA1, the second pixel area PA2, and/or the third pixel area PA3.

The light-emitting element layer LEL may be located on the pixel circuit layer PCL. The light-emitting element layer LEL may include a light-emitting element. In one or more embodiments, the light-emitting element layer LEL may include a first light-emitting element LE1, a second light-emitting element LE2, and a third light-emitting element LE3. The first light-emitting element LE1 may be arranged in the first pixel area PA1. The second light-emitting element LE2 may be arranged in the second pixel area PA2. The third light-emitting element LE3 may be arranged in the third pixel area PA3.

A light-emitting element may be an organic light-emitting diode including an organic emission layer. Alternatively, the light-emitting element may be a light-emitting diode (LED) including an inorganic emission layer. A size of an LED may be in a micro scale or a nano scale. For example, the LED may be a micro LED. Alternatively, the LED may be a nanorod LED. The nanorod LED may include gallium nitride (GaN). In one or more embodiments, a color converting layer may be located above the nanorod LED. The color converting layer may include quantum dots. Alternatively, the light-emitting element may be a quantum dot LED including a quantum dot emission layer. Hereinafter, a case where a light-emitting element is an organic light-emitting diode will be mainly described in detail.

The encapsulation layer 300 may be located on the display layer DSL. The encapsulation layer 300 may be located on the light-emitting element layer LEL. In one or more embodiments, the encapsulation layer 300 may include at least one inorganic encapsulation layer. In one or more embodiments, the encapsulation layer 300 may include at least one inorganic encapsulation layer and at least one organic encapsulation layer. In one or more embodiments, the encapsulation layer 300 may include a first inorganic encapsulation layer 310, an organic encapsulation layer 320, and a second inorganic encapsulation layer 330, which are sequentially stacked. In one or more embodiments, the organic encapsulation layer 320 and the second inorganic encapsulation layer 330 may be omitted.

The first inorganic encapsulation layer 310 may cover the first light-emitting element LE1, the second light-emitting element LE2, and the third light-emitting element LE3. The first inorganic encapsulation layer 310 may extend from the first pixel area PA1 to the second pixel area PA2 across the substrate opening portion 100OP. The first inorganic encapsulation layer 310 may extend from the first pixel area PA1 to the second pixel area PA2 via the opening area OPA. The first inorganic encapsulation layer 310 may extend from the first pixel area PA1 to the opening area OPA, and may extend from the opening area OPA to the second pixel area PA2. The first inorganic encapsulation layer 310 may extend along an inner side surface of the insulating layer IL defining the insulating layer opening ILOP. The first inorganic encapsulation layer 310 may extend along an inner side surface of the substrate 100 defining the substrate opening portion 100OP. The first inorganic encapsulation layer 310 may extend from a portion of the inner side surface of the substrate 100 defining the substrate opening portion 100OP to another portion of the inner side surface of the substrate 100 defining the substrate opening portion 100OP. The first inorganic encapsulation layer 310 may prevent or reduce penetration of moisture or foreign substances from the opening area OPA into the light-emitting element layer LEL.

The organic encapsulation layer 320 may be located on the first inorganic encapsulation layer 310. The organic encapsulation layer 320 may include a first organic encapsulation portion 320A, a second organic encapsulation portion 320B, and a third encapsulation portion (or a third organic encapsulation portion) 320C. The first organic encapsulation portion 320A, the second organic encapsulation portion 320B, and the third encapsulation portion 320C may be integrally provided. The first organic encapsulation portion 320A may overlap the first light-emitting element LE1 in a plan view. The second organic encapsulation portion 320B may overlap the second light-emitting element LE2 in a plan view. The third encapsulation portion 320C may overlap the substrate opening portion 100OP in a plan view, and may extend between the first light-emitting element LE1 and the second light-emitting element LE2. The third encapsulation portion 320C may be arranged in the substrate opening portion 100OP and the insulating layer opening ILOP. In the present embodiments, the substrate 100 may include the opening area OPA to reduce or prevent a reduction in the light transmittance or sound transmittance due to the substrate 100. Because a large portion of the opening area OPA is arranged with the third encapsulation portion 320C having high light transmittance or sound transmittance, the light transmittance or the sound transmittance of the display panel 10 may be increased in the transmission area TA. The second inorganic encapsulation layer 330 may be located on the organic encapsulation layer 320.

The at least one inorganic encapsulation layer may include at least one inorganic material from among aluminum oxide (Al₂O₃), titanium oxide (TiO₂), tantalum oxide (Ta₂O₅), zinc oxide (ZnOₓ), silicon oxide (SiO₂), silicon nitride (SiNₓ), and silicon oxynitride (SiOₓN_{y}). The zinc oxide (ZnOₓ) may be zinc oxide (ZnO) and/or zinc peroxide (ZnO₂). The at least one organic encapsulation layer may include a polymer-based material. The polymer-based material may include an acrylic resin, an epoxy resin, polyimide, polyethylene, or the like. As one or more embodiments, the at least one organic encapsulation layer may include acrylate.

The touch sensor layer 400 may be located on the encapsulation layer 300.

The touch sensor layer 400 may sense coordinate information according to an external input, for example, a touch event. The touch sensor layer 400 may include a sensor electrode and touch wires connected to the sensor electrode. The touch sensor layer 400 may sense an external input by using a self-capacitive method or a mutual capacitive method. The touch sensor layer 400 may be formed on the encapsulation layer 300. Alternatively, the touch sensor layer 400 may be separately formed on a touch substrate and then bonded to the encapsulation layer 300 through an adhesive layer, such as an optically clear adhesive. In one or more embodiments, the touch sensor layer 400 may be directly formed on the encapsulation layer 300. In this case, an adhesive layer may not be between the touch sensor layer 400 and the encapsulation layer 300.

The anti-reflection layer 500 may be located on the touch sensor layer 400. The anti-reflection layer 500 may reduce the reflectance of light (e.g., external light) incident from the outside toward the display device 1. The anti-reflection layer 500 may have an anti-reflection layer opening portion 500OP overlapping the transmission area TA and/or the opening area OPA in a plan view. Accordingly, the light transmittance or sound transmittance of the display panel 10 may be increased in the transmission area TA and/or the opening area OPA.

The anti-reflection layer 500 may include a circular polarizer. In one or more embodiments, the anti-reflection layer 500 may include a retarder and a polarizer. The retarder may be a film type or a liquid-crystal coating type, and may include a λ/2 retarder and/or a λ/4 retarder. The polarizer may also be a film type or a liquid-crystal coating type. The film-type polarizer may include a stretch-type synthetic resin film, and the liquid-crystal-coating-type polarizer may include liquid crystals in a corresponding arrangement. The retarder and the polarizer may further include a protective film.

As one or more other embodiments, the anti-reflection layer 500 may include a black matrix and color filters. The color filters may be arranged considering a color of light emitted from each of a plurality of pixels of the display device 1. Each of the color filters may include red, green, or blue pigments or dyes. Alternatively, each of the color filters may further include quantum dots in addition to the pigments or dyes stated above. Alternatively, some of the color filters may omit the pigments or dyes stated above, and may include scattering particles, such as titanium oxide.

As one or more other embodiments, the anti-reflection layer 500 may include a destructive interference structure. The destructive interference structure may include a first reflective layer and a second reflective layer, which are on different layers. First reflected light and second reflected light respectively reflected by the first reflective layer and the second reflective layer may destructively interfere with each other, and accordingly, the reflectance of external light may be reduced.

In some embodiments, a window may be located on the anti-reflection layer 500. The window may protect components located below the window. The window may include at least one of glass, sapphire, and plastic. The window may be, for example, an ultra-thin glass or a colorless polyimide.

The component COMP may overlap the display panel 10 in a plan view. In a plan view, the component COMP may overlap the transmissive display area TDA. In one or more embodiments, in a plan view, the component COMP may overlap the first pixel area PA1, the opening area OPA, and the second pixel area PA2. In one or more embodiments, the component COMP may be spaced apart from the display panel 10. In one or more other embodiments, the component COMP may be attached to the display panel 10.

The component COMP may include an electronic element. For example, the electronic element may include a sensor for receiving and using light, such as an infrared sensor, a camera for capturing an image by receiving light, a sensor for outputting and sensing light or sound to measure a distance or recognize a fingerprint or the like, a small lamp for outputting light, and/or a speaker for outputting sound. An electronic element for using light may use light having various wavelengths, such as visible light, infrared light, and/or ultraviolet light.

In one or more embodiments, the component COMP may include sub-components, such as a light-emitting unit and a light receiving unit. The light-emitting unit and the light receiving unit may have an integrated structure or a physically separated structure, such that a pair of the light-emitting unit and the light receiving unit may form a single component COMP.

The lower protective film PB may support and protect the substrate 100.

The lower protective film PB may have an opening PB_OP overlapping the transmissive display area TDA in a plan view, and the component COMP may be arranged in the opening PB_OP. The lower protective film PB may include polyethylene terephthalate or polyimide.

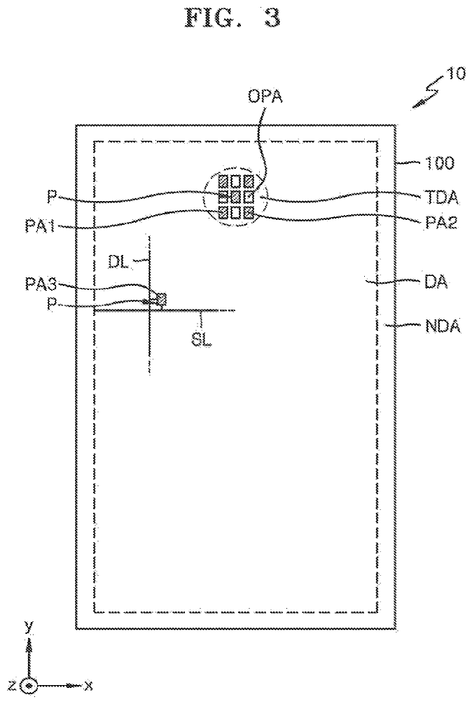

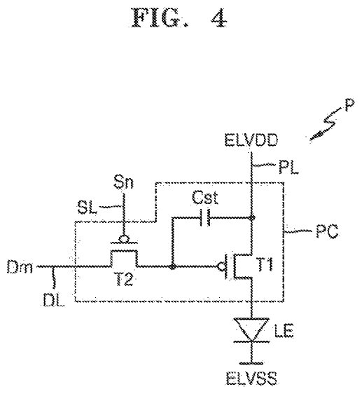

FIG. 3 is a schematic plan view of the display panel 10 according to one or more embodiments. FIG. 4 is an equivalent circuit diagram schematically illustrating a pixel P of a display device.

Referring to FIGS. 3 and 4, the display panel 10 may include the substrate 100, the pixel P, a scan line SL, and a data line DL. The substrate 100 may include the transmissive display area TDA, the display area DA, and the non-display area NDA. The transmissive display area TDA may include the first pixel area PA1, the second pixel area PA2, and the opening area OPA. The opening area OPA may have a substrate opening portion. The display area DA may include the third pixel area PA3.

A pixel P may be arranged in each of the transmissive display area TDA and the display area DA. A plurality of pixels P may be provided. The plurality of pixels P may be arranged in the first pixel area PA1, the second pixel area PA2, and/or the third pixel area PA3. The pixel P may be omitted from the transmission area TA of FIG. 2.

The pixel P may be connected to the scan line SL extending in a first direction, and the data line DL extending in a second direction crossing the first direction. The first direction may be, for example, an x direction of FIG. 3. The second direction may be, for example, a y direction of FIG. 3.

The pixel P may include a pixel circuit PC, and a light-emitting element LE electrically connected to the pixel circuit PC. In one or more embodiments, the pixel circuit PC may include a first transistor T1, a second transistor T2, and a storage capacitor Cst.

The second transistor T2 may be a switching transistor. The second transistor T2 may be connected to the scan line SL and the data line DL, and may deliver, to the first transistor T1, a data signal Dm input from the data line DL, according to a scan signal Sn input from the scan line SL.

The storage capacitor Cst may be connected to the second transistor T2 and to a driving voltage line PL, and may store a voltage corresponding to a difference between a voltage received from the second transistor T2 and a first power voltage ELVDD supplied to the driving voltage line PL.

The first transistor T1 may be a driving transistor. The first transistor T1 may be connected to the driving voltage line PL and the storage capacitor Cst, and may control a driving current flowing from the driving voltage line PL to a light-emitting element LE in accordance with a voltage value stored in the storage capacitor Cst. The light-emitting element LE may emit light having a corresponding brightness according to the driving current. An opposite electrode (e.g., a cathode) of the light-emitting element LE may receive a second power voltage ELVSS.

Although FIG. 4 illustrates that the pixel circuit PC includes two transistors and one storage capacitor, in one or more other embodiments, the pixel circuit PC may include three or more transistors.

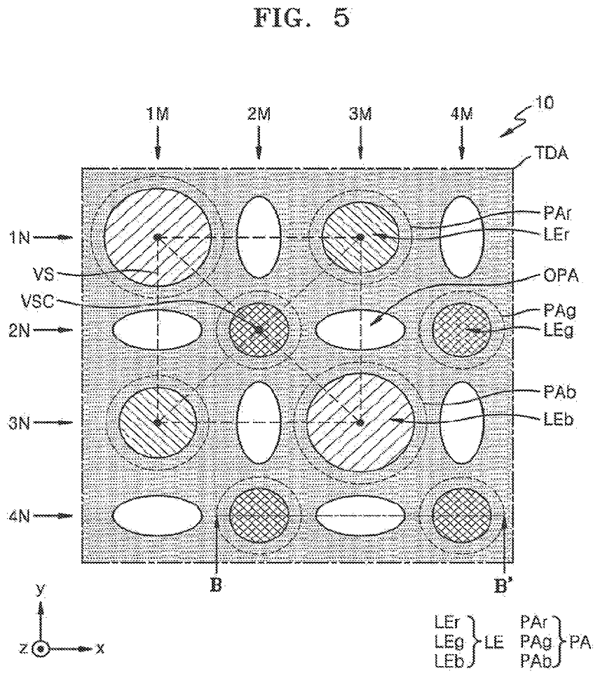

FIG. 5 is a plan view schematically illustrating the transmissive display area TDA of the display panel 10 according to one or more embodiments.

Referring to FIG. 5, the display panel 10 may include the substrate 100 in FIG. 3 and the light-emitting element LE. The substrate 100 in FIG. 3 may include the transmissive display area TDA. The transmissive display area TDA may include a pixel area PA and the opening area OPA. In one or more embodiments, the pixel area PA may include a red pixel area PAr, a green pixel area PAg, and a blue pixel area PAb.

The opening area OPA may be between a first pixel area and a second pixel area. The opening areas OPA may be between adjacent pixel areas, respectively. For example, the opening area OPA may be between the red pixel area PAr and the green pixel area PAg. The opening area OPA may be between the green pixel area PAg and the blue pixel area PAb. The opening area OPA may be between the blue pixel area PAb and the red pixel area PAr. The opening area OPA may have a substrate opening portion. In one or more embodiments, in a plan view, the shape of the substrate opening portion may be a circular shape or an elliptical shape. In one or more other embodiments, in a plan view, the substrate opening portion may have a curved shape. In one or more other embodiments, in a plan view, the substrate opening portion may have a polygonal shape. The opening area OPA may be formed through an etching operation. In this case, the opening areas OPA may be precisely formed between adjacent pixel areas, respectively.

The light-emitting element LE may be arranged in the transmissive display area TDA. A plurality of light-emitting elements LE may be provided. In one or more embodiments, the light-emitting element LE may include a red light-emitting element LEr, a green light-emitting element LEg, and a blue light-emitting element LEb. The red light-emitting element LEr may emit light having a red wavelength band. The green light-emitting element LEg may emit light having a green wavelength band. The blue light-emitting element LEb may emit light having a blue wavelength band. The red light-emitting element LEr may be arranged in the red pixel area PAr. The green light-emitting element LEg may be arranged in the green pixel area PAg. The blue light-emitting element LEb may be arranged in the blue pixel area PAb. An emission area of the blue light-emitting element LEb may be greater than an emission area of the red light-emitting element LEr. The emission area of the red light-emitting element LEr may be greater than an emission area of the green light-emitting element LEg. In one or more other embodiments, the light-emitting element LE may include the red light-emitting element LEr, the green light-emitting element LEg, the blue light-emitting element LEb, and a white light-emitting element. Hereinafter, a case in which the red light-emitting element LEr, the green light-emitting element LEg, and the blue light-emitting element LEb are located on the substrate 100 will be mainly described in detail.

A plurality of red light-emitting elements LEr and a plurality of blue light-emitting elements LEb may be alternately arranged in a first row 1N. In a second row 2N adjacent to the first row 1N, a plurality of green light-emitting elements LEg may be arranged to be spaced apart from one another by a corresponding interval. In a third row 3N adjacent to the second row 2N, the plurality of red light-emitting elements LEr and the plurality of blue light-emitting elements LEb may be alternately arranged. In a fourth row 4N adjacent to the third row 3N, the plurality of green light-emitting elements LEg may be arranged to be spaced apart from one another in a corresponding interval. Such an arrangement of the light-emitting elements LE may be repeated.

The plurality of red light-emitting elements LEr and the plurality of blue light-emitting elements LEb arranged in the first row 1N may be alternately arranged with the plurality of green light-emitting elements LEg arranged in the second row 2N. The plurality of blue light-emitting elements LEb and the plurality of red light-emitting elements LEr may be alternately arranged in a first column 1M. In a second column 2M adjacent to the first column 1M, the plurality of green light-emitting elements LEg may be arranged to be spaced apart from one another by a corresponding interval. In a third column 3M adjacent to the second column 2M, the plurality of blue light-emitting elements LEb and the plurality of red light-emitting elements LEr may be alternately arranged. In a fourth column 4M adjacent to the third column 3M, the plurality of green light-emitting elements LEg may be arranged to be spaced apart from one another by a corresponding interval. Such an arrangement of the light-emitting elements LE may be repeated.

When such an arrangement structure of the light-emitting elements LE are expressed differently, the green light-emitting element LEg may be arranged at the center of a virtual quadrangle VS. In one or more embodiments, a center point of the green light-emitting element LEg may be a center point VSC of the virtual quadrangle VS. The red light-emitting element LEr and the blue light-emitting element LEb may be respectively arranged at vertices of the virtual quadrangle VS. In one or more embodiments, the blue light-emitting element LEb may be arranged at first and third vertices arranged opposite to each other with respect to the center point VSC of the virtual quadrangle VS among the vertices of the virtual quadrangle VS. The red light-emitting element LEr may be arranged at second and fourth vertices arranged opposite to each other with respect to the center point VSC of the virtual quadrangle VS among the vertices of the virtual quadrangle VS.

Such an arrangement structure of the light-emitting elements LE may be referred to as a PenTile Matrix® structure or a PenTile® structure (e.g., a RGBG matrix structure, a PENTILE® matrix structure, a PENTILE® structure, or an RGBG structure, PENTILE® being a registered trademark of Samsung Display Co., Ltd., Republic of Korea). High resolution may be implemented by a small number of light-emitting elements by applying a rendering structure that expresses colors by sharing adjacent light-emitting elements.

Although FIG. 5 illustrates that the red light-emitting element LEr, the green light-emitting element LEg, and the blue light-emitting element LEb are arranged in a PenTile Matrix® structure, the present disclosure is not limited thereto. In one or more other embodiments, the red light-emitting element LEr, the green light-emitting element LEg, and the blue light-emitting element LEb may be arranged in various arrangement methods, such as a stripe structure, a mosaic arrangement structure, a delta arrangement structure, or the like.

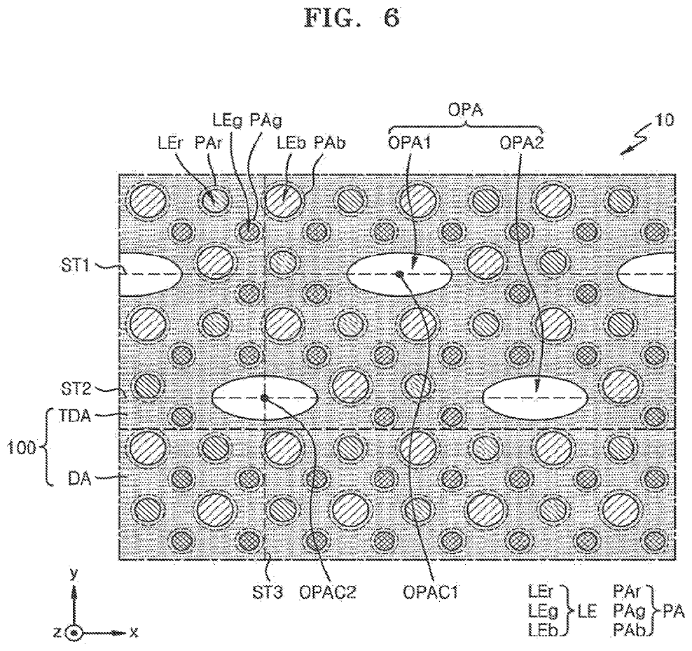

FIG. 6 is a plan view schematically illustrating the transmissive display area TDA and the display area DA of the display panel 10 according to one or more embodiments.

Referring to FIG. 6, the display panel 10 may include the substrate 100 in FIG. 3 and the light-emitting element LE. The substrate 100 in FIG. 3 may include the transmissive display area TDA and the display area DA. The transmissive display area TDA may include the pixel area PA and the opening area OPA. In one or more embodiments, the pixel area PA may include the red pixel area PAr, the green pixel area PAg, and the blue pixel area PAb. The opening area OPA may be between a first pixel area and a second pixel area. The opening area OPA may have a substrate opening portion. In one or more embodiments, in a plan view, the shape of the substrate opening portion may be a circular shape or an elliptical shape. In one or more other embodiments, in a plan view, the substrate opening portion may have a curved shape. In one or more other embodiments, in a plan view, the substrate opening portion may have a polygonal shape.

A plurality of opening areas OPA may be provided in the transmissive display area TDA. In other words, the opening area OPA may include a plurality of opening areas OPA in the transmissive display area TDA. The plurality of opening areas OPA may include a plurality of first opening areas OPA1 and a plurality of second opening areas OPA2. The plurality of first opening areas OPA1 may be spaced apart from one another along a virtual first straight line ST1 extending in a first direction (e.g., x direction). Centers OPAC1 of the plurality of first opening areas OPA1 may be on the virtual first straight line ST1. The plurality of second opening areas OPA2 may be spaced apart from one another along a virtual second straight line ST2 extending in the first direction (e.g., x direction). The virtual second straight line ST2 may be parallel to the virtual first straight line ST1. Centers OPAC2 of the plurality of second opening areas OPA2 may be on the virtual second straight line ST2.

The plurality of first opening areas OPA1 and the plurality of second opening areas OPA2 may be alternately arranged. A virtual third straight line ST3 may be arranged between adjacent first opening areas OPA1 among the plurality of first opening areas OPA1. The virtual third straight line ST3 may extend in a second direction (e.g., y direction) intersecting with the first direction (e.g., x direction). The virtual third straight line ST3 may pass through a center OPAC2 of any one of the plurality of second opening areas OPA2.

The light-emitting element LE may be arranged in the display area DA and the transmissive display area TDA. A plurality of light-emitting elements LE may be provided. In one or more embodiments, the light-emitting element LE may include the red light-emitting element LEr, the green light-emitting element LEg, and the blue light-emitting element LEb. The red light-emitting element LEr, the green light-emitting element LEg, and the blue light-emitting element LEb may be arranged in a PenTile® structure in the transmissive display area TDA. The plurality of light-emitting elements LE may surround the opening area OPA in the transmissive display area TDA. The red light-emitting element LEr, the green light-emitting element LEg, and the blue light-emitting element LEb may be arranged in a PenTile® structure in the display area DA.

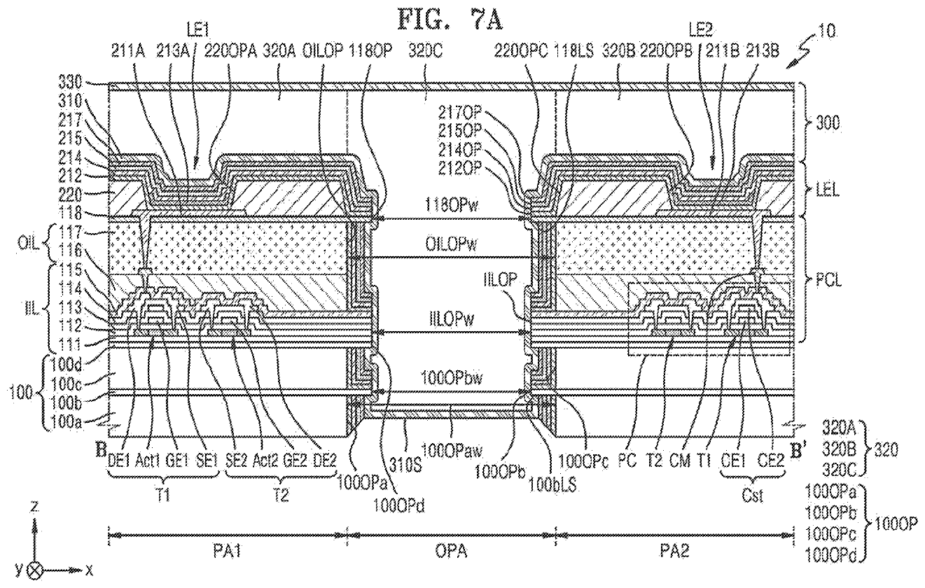

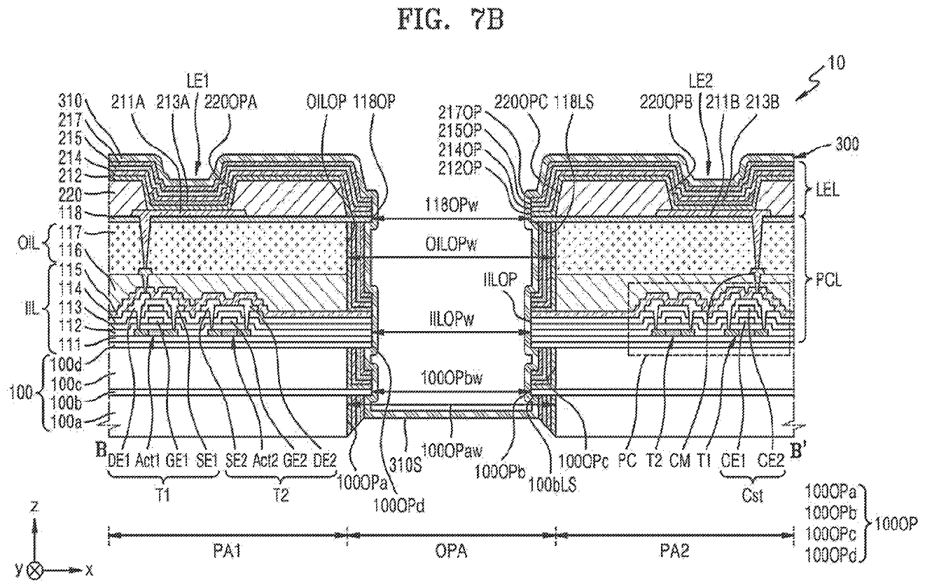

FIGS. 7A and 7B are cross-sectional views each schematically illustrating the display panel 10 taken along the line B-B′ of FIG. 5, according to one or more embodiments.

Referring to FIGS. 7A and 7B, the display panel 10 may include the substrate 100, the pixel circuit layer PCL, the light-emitting element layer LEL, and the encapsulation layer 300. The substrate 100 may include the first pixel area PA1, the second pixel area PA2, and the opening area OPA. The opening area OPA may be between the first pixel area PA1 and the second pixel area PA2. The opening area OPA may have the substrate opening portion 100OP. The substrate 100 may include an organic substrate layer, and an inorganic substrate layer located on the organic substrate layer. The organic substrate layer may have, or may define, an organic substrate opening portion included in the substrate opening portion 100OP, and the inorganic substrate layer may include, or define, an inorganic substrate opening portion included in the substrate opening portion 100OP. In one or more embodiments, the substrate 100 may include a first organic substrate layer 100a, a first inorganic substrate layer 100b, a second organic substrate layer 100c, and a second inorganic substrate layer 100d. The first organic substrate layer 100a, the first inorganic substrate layer 100b, the second organic substrate layer 100c, and the second inorganic substrate layer 100d may be sequentially stacked. The first organic substrate layer 100a may have, or define, a first organic substrate opening portion 100OPa. The first inorganic substrate layer 100b may have, or define, a first inorganic substrate opening portion 100OPb. The second organic substrate layer 100c may have, or define, a second organic substrate opening portion 100OPc. The second inorganic substrate layer 100d may have, or define, a second inorganic substrate opening portion 100OPd. The first organic substrate opening portion 100OPa, the first inorganic substrate opening portion 100OPb, the second organic substrate opening portion 100OPc, and the second inorganic substrate opening portion 100OPd may be included in the substrate opening portion 100OP.

A width of an organic substrate opening portion may be greater than a width or an inorganic substrate opening portion. For example, a width 100OPaw of the first organic substrate opening portion 100OPa may be greater than a width 100OPbw of the first inorganic substrate opening portion 100OPb. A width of the second organic substrate opening portion 100OPc may be greater than a width of the second inorganic substrate opening portion 100OPd. The first inorganic substrate layer 100b may protrude from the first pixel area PA1 or the second pixel area PA2 to the opening area OPA. In other words, the first inorganic substrate layer 100b have one or more protruding tips protruding to a center of the opening area OPA. The second inorganic substrate layer 100d may protrude from the first pixel area PA1 or the second pixel area PA2 to the opening area OPA.

At least one of the first organic substrate layer 100a and the second organic substrate layer 100c may include a polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like.

The first inorganic substrate layer 100b and the second inorganic substrate layer 100d are barrier layers configured to reduce or prevent penetration of external foreign substances, and each may be a single layer or a multi-layer, each including an inorganic material, such as silicon nitride (SiNₓ), silicon oxide (SiO₂), and/or silicon oxynitride (SiOₓN_{y}).

The pixel circuit layer PCL may be located on the substrate 100. The pixel circuit layer PCL may include an insulating layer, the pixel circuit PC, a connection electrode CM, and an inorganic layer 118. The insulating layer may include an inorganic insulating layer IIL and an organic insulating layer OIL. The inorganic insulating layer IIL may be arranged between the substrate 100 and the light-emitting element layer LEL. The organic insulating layer OIL may be arranged between the inorganic insulating layer IIL and the light-emitting element layer LEL. The organic insulating layer OIL may be a planarization layer. In one or more embodiments, the organic insulating layer OIL may be between the inorganic insulating layer IIL and the inorganic layer 118.

The insulating layer may have an insulating layer opening portion overlapping the substrate opening portion 100OP in a plan view. The inorganic insulating layer IIL may have an inorganic insulating layer opening portion IILOP overlapping the substrate opening portion 100OP in a plan view. The organic insulating layer OIL may have an organic insulating layer opening portion OILOP overlapping the substrate opening portion 100OP in a plan view. A width OILOPw of the organic insulating layer opening portion OILOP may be greater than a width IlLOPw of the inorganic insulating layer opening portion IILOP. The inorganic insulating layer IIL may protrude from the first pixel area PA1 and/or the second pixel area PA2 to the opening area OPA. The second inorganic substrate layer 100d and the inorganic insulating layer IIL may each have one or more protruding tips protruding toward the center of the opening area OPA.

The inorganic layer 118 may have an inorganic layer opening portion 118OP overlapping the substrate opening portion 100OP in a plan view. The width OILOPw of the organic insulating layer opening portion OILOP may be greater than a width 118OPw of the inorganic layer opening portion 118OP. In one or more embodiments, the width 118OPw of the inorganic layer opening portion 118OP may be about 10 μm to about 80 μm. The inorganic layer 118 may protrude from the first pixel area PA1 and/or the second pixel area PA2 to the opening area OPA. The inorganic layer 118 may have one or more protruding tips protruding toward the center of the opening area OPA.

In one or more embodiments, the inorganic insulating layer IIL may include a buffer layer 111, a first gate insulating layer 112, a second gate insulating layer 113, an interlayer insulating layer 114, and a lower inorganic layer 115. The organic insulating layer OIL may include a first organic insulating layer 116 and a second organic insulating layer 117. The pixel circuit PC may include the first transistor T1, the second transistor T2, and the storage capacitor Cst. The first transistor T1 may include a first semiconductor layer Act1, a first gate electrode GE1, a first source electrode SE1, and a first drain electrode DE1. The second transistor T2 may include a second semiconductor layer Act2, a second gate electrode GE2, a second source electrode SE2, and a second drain electrode DE2. The storage capacitor Cst may include a first capacitor electrode CE1 and a second capacitor electrode CE2.

The buffer layer 111 may be located on the substrate 100. The buffer layer 111 may include an inorganic insulating material, such as silicon nitride (SiNₓ), silicon oxynitride (SiOₓN_{y}), and silicon oxide (SiO₂), and may include a single layer or a multi-layer, each including the above-stated inorganic insulating material. In one or more embodiments, the buffer layer 111 may be omitted.

The first semiconductor layer Act1 and the second semiconductor layer Act2 may be located on the buffer layer 111. At least one of the first semiconductor layer Act1 and the second semiconductor layer Act2 may include polysilicon. Alternatively, at least one of the first semiconductor layer Act1 and the second semiconductor layer Act2 may include amorphous silicon, an oxide semiconductor, an organic semiconductor, or the like. At least one of the first semiconductor layer Act1 and the second semiconductor layer Act2 may include a channel area, a drain area, and a source area, wherein the drain area and the source area are arranged on respective sides of the channel area.

The first gate insulating layer 112 may be located on the first semiconductor layer Act1, the second semiconductor layer Act2, and the buffer layer 111. The first gate insulating layer 112 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnOₓ), or the like. The zinc oxide (ZnOₓ) may include zinc oxide (ZnO) and/or zinc peroxide (ZnO₂).

The first gate electrode GE1 and the second gate electrode GE2 may be located on the first gate insulating layer 112. In a plan view, the first gate electrode GE1 may overlap the channel area of the first semiconductor layer Act1. In a plan view, the second gate electrode GE2 may overlap the channel area of the second semiconductor layer Act2. At least one of the first gate electrode GE1 and the second gate electrode GE2 may include a low-resistance metal material. In one or more embodiments, at least one of the first gate electrode GE1 and the second gate electrode GE2 may include a conductive material including molybdenum (Mo), aluminum (Al), copper (Cu), titanium (Ti), etc., and may include a single layer or a multi-layer, each including the above-described material.

The second gate insulating layer 113 may be located on the first gate insulating layer 112, the first gate electrode GE1, and the second gate electrode GE2. The second gate insulating layer 113 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnOₓ), or the like.

The second capacitor electrode CE2 may be located on the second gate insulating layer 113. In a plan view, the second capacitor electrode CE2 may overlap the first gate electrode GE1. In this case, the first gate electrode GE1 may function as the first capacitor electrode CE1 of the storage capacitor Cst. Although FIGS. 7A and 7B each illustrate that the storage capacitor Cst overlaps the first transistor T1 in a plan view, in one or more other embodiments, the storage capacitor Cst might not overlap the first transistor T1 in a plan view. In this case, the first capacitor electrode CE1 and the first gate electrode GE1 may be separate electrodes. The second capacitor electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may include a single layer or a multi-layer, each including the above-stated material.

The interlayer insulating layer 114 may be located on the second gate insulating layer 113 and the second capacitor electrode CE2. The interlayer insulating layer 114 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnOₓ), or the like.

The first source electrode SE1, the first drain electrode DE1, the second source electrode SE2, and the second drain electrode DE2 may be located on the interlayer insulating layer 114. Each of the first source electrode SE1 and the first drain electrode DE1 may be connected to the first semiconductor layer Act1 through contact holes included in the first gate insulating layer 112, the second gate insulating layer 113, and the interlayer insulating layer 114. Each of the second source electrode SE2 and the second drain electrode DE2 may be connected to the second semiconductor layer Act2 through contact holes included in the first gate insulating layer 112, the second gate insulating layer 113, and the interlayer insulating layer 114. At least one of the first source electrode SE1, the first drain electrode DE1, the second source electrode SE2, and the second drain electrode DE2 may include a conductive material including Mo, Al, Cu, or Ti, and may include a multi-layer or a single layer including the above materials. In one or more embodiments, at least one of the first source electrode SE1, the first drain electrode DE1, the second source electrode SE2, and the second drain electrode DE2 may have a multi-layered structure of Ti/Al/Ti.

The lower inorganic layer 115 may be located on the first source electrode SE1, the first drain electrode DE1, the second source electrode SE2, the second drain electrode DE2, and the interlayer insulating layer 114. The lower inorganic layer 115 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnOₓ), or the like. In some embodiments, the lower inorganic layer 115 may be omitted.

The first organic insulating layer 116 may be located on the lower inorganic layer 115. The first organic insulating layer 116 may include an organic material. The first organic insulating layer 116 may include a general commercial polymer such as poly(methyl methacrylate) (PMMA) or polystyrene (PS), a polymer derivative having a phenol group, and an organic insulating material such as an acrylic polymer, an imide polymer, an aryl ether polymer, an amide polymer, a fluorine polymer, a p-xylene polymer, a vinyl alcohol polymer, and a mixture thereof.

The connection electrode CM may be located on the first organic insulating layer 116. The connection electrode CM may be connected to the pixel circuit PC through a contact hole of the first organic insulating layer 116. In one or more embodiments, the connection electrode CM may be connected to the first drain electrode DE1 or the first source electrode SE1 through the contact hole of the first organic insulating layer 116. The connection electrode CM may include a material having good conductivity. The connection electrode CM may include a conductive material including Mo, Al, Cu, Ti, or the like, and may include a multi-layer or a single layer, each including the above material. As one or more embodiments, the connection electrode CM may have a multi-layered structure of Ti/Al/Ti.

The second organic insulating layer 117 may be located on the connection electrode CM and the first organic insulating layer 116. The second organic insulating layer 117 may include a general commercial polymer, such as PMMA or PS, a polymer derivative having a phenol group, and an organic insulating material such as an acrylic polymer, an imide polymer, an aryl ether polymer, an amide polymer, a fluorine polymer, a p-xylene polymer, a vinyl alcohol polymer, and a mixture thereof.

The inorganic layer 118 may be located on the second organic insulating layer 117. The inorganic layer 118 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnOₓ), or the like. In some embodiments, the inorganic layer 118 may be omitted.

The light-emitting element layer LEL may be located on the pixel circuit layer PCL. The light-emitting element layer LEL may include the first light-emitting element LE1 and the second light-emitting element LE2. Each of the first light-emitting element LE1 and the second light-emitting element LE2 may include an organic light-emitting diode. The first light-emitting element LE1 may be arranged in the first pixel area PA1. The second light-emitting element LE2 may be arranged in the second pixel area PA2. In one or more embodiments, the light-emitting element layer LEL may include a first pixel electrode 211A, a second pixel electrode 211B, a first functional layer 212, a first emission layer 213A, a second emission layer 213B, a second functional layer 214, an opposite electrode 215, a capping layer 217, and a pixel defining layer 220.

The first pixel electrode 211A and the second pixel electrode 211B may be located on the inorganic layer 118 and/or the organic insulating layer OIL. The first pixel electrode 211A may be arranged in the first pixel area PA1. The second pixel electrode 211B may be arranged in the second pixel area PA2. In one or more embodiments, a width of at least one of the first pixel electrode 211A and the second pixel electrode 211B may be about 9 μm to about 30 μm. A width of the at least one of the first pixel electrode 211A and the second pixel electrode 211B may be a length of at least one of the first pixel electrode 211A and the second pixel electrode 211B in a first direction (e.g., x direction). The at least one of the first pixel electrode 211A and the second pixel electrode 211 B may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The at least one of the first pixel electrode 211A and the second pixel electrode 211B may include a reflective film including Ag, Mg, Al, Pt, Pd, Au, Ni, Nd, Ir, Cr, or a compound thereof. The at least one of the first pixel electrode 211A and the second pixel electrode 211B may further include a film including ITO, IZO, ZnO, or In₂O₃ above/below the above-described reflective film.

The pixel defining layer 220 may cover one or more edges of the first pixel electrode 211A and one or more edges of the second pixel electrode 211B. The pixel defining layer 220 may have a first pixel opening portion 220OPA, a second pixel opening portion 220OPB, and an intermediate opening portion 220OPC. The first pixel opening portion 220OPA may overlap the first pixel electrode 211A in a plan view. The second pixel opening portion 220OPB may overlap the second pixel electrode 211B in a plan view. The first pixel opening portion 220OPA may define an emission area of the first light-emitting element LE1. The second pixel opening portion 220OPB may define an emission area of the second light-emitting element LE2. In a plan view, the intermediate opening portion 220OPC may overlap the substrate opening portion 100OP. In one or more embodiments, a distance from the first pixel opening portion 220OPA to the intermediate opening portion 220OPC in the first direction (e.g., x direction) may be about 8 μm. In one or more embodiments, a distance from the second pixel opening portion 220OPB to the intermediate opening portion 220OPC in the first direction (e.g., x direction) may be about 8 μm. The pixel defining layer 220 may include an organic insulating material and/or an inorganic insulating material. In some embodiments, the pixel defining layer 220 may include a light-blocking material.

The first functional layer 212 may be located on the first pixel electrode 211A, the second pixel electrode 211B, and the pixel defining layer 220. In one or more embodiments, the first functional layer 212 may be arranged between the first pixel electrode 211A and the first emission layer 213A. The first functional layer 212 may be arranged between the second pixel electrode 211B and the second emission layer 213B. The first functional layer 212 may have, or define, a first functional layer opening portion 212OP overlapping the substrate opening portion 100OP in a plan view. The first functional layer 212 may include a hole transport layer (HTL), or may include an HTL and a hole injection layer (HIL). In some embodiments, a first portion of the first functional layer 212 may located on an inner side surface of the first organic substrate layer 100a defining the first organic substrate opening portion 100OPa. A second portion of the first functional layer 212 may be located on an inner side surface of the second organic substrate layer 100c defining the second organic substrate opening portion 100OPc. A third portion of the first functional layer 212 may be located on an inner side surface of the organic insulating layer OIL defining the organic insulating layer opening portion OILOP.

The first emission layer 213A and the second emission layer 213B may be located on the first functional layer 212. The first emission layer 213A may be located above the first pixel electrode 211A. The second emission layer 213B may be located above the second pixel electrode 211B. The first emission layer 213A and the second emission layer 213B may each include a polymer organic material or a low-molecular-weight organic material that emits light of a corresponding color.

The second functional layer 214 may be located on the first emission layer 213A, the second emission layer 213B, and the first functional layer 212. The second functional layer 214 may be between the first emission layer 213A and the opposite electrode 215. The second functional layer 214 may be between the second emission layer 2136 and the opposite electrode 215. The second functional layer 214 may have a second functional layer opening portion 214OP overlapping the substrate opening portion 100OP in a plan view. The second functional layer 214 may include an electron transport layer (ETL) and/or an electron injection layer (EIL). In some embodiments, a first portion of the second functional layer 214 may be located on the inner side surface of the first organic substrate layer 100a defining the first organic substrate opening portion 100OPa (e.g., with the first functional layer 212 therebetween). A second portion of the second functional layer 214 may be located on the inner side surface of the second organic substrate layer 100c defining the second organic substrate opening portion 100OPc (e.g., with the first functional layer 212 therebetween). A third portion of the second functional layer 214 may be located on the inner side surface of the organic insulating layer OIL defining the organic insulating layer opening portion OILOP (e.g., with the first functional layer 212 therebetween).

The opposite electrode 215 may be located on the second functional layer 214. The opposite electrode 215 may have an opposite electrode opening portion 215OP overlapping the substrate opening portion 100OP in a plan view. The opposite electrode 215 may include a conductive material having a low work function. For example, the opposite electrode 215 may include a (semi)transparent layer, the (semi)transparent layer including Ag, Mg, Al, Pt, Pd, Au, Ni, Nd, Ir, Cr, lithium (Li), Ca, alloys thereof, or the like. Alternatively, the opposite electrode 215 may further include a layer such as ITO, IZO, ZnO, or In₂O₃ above the (semi)transparent layer including the above-stated material. In some embodiments, a first portion of the opposite electrode 215 may be located on the inner side surface of the first organic substrate layer 100a defining the first organic substrate opening portion 100OPa (e.g., with the first functional layer 212 and the second functional layer 214 therebetween). A second portion of the opposite electrode 215 may be located on the inner side surface of the second organic substrate layer 100c defining the second organic substrate opening portion 100OPc (e.g., with the first functional layer 212 and the second functional layer 214 therebetween). A third portion of the opposite electrode 215 may be located on the inner side surface of the organic insulating layer OIL defining the organic insulating layer opening portion OILOP (e.g., with the first functional layer 212 and the second functional layer 214 therebetween).

Components stacked from the first pixel electrode 211A to the opposite electrode 215 in the first pixel area PA1 may configure the first light-emitting element LE1. Components stacked from the second pixel electrode 211B to the opposite electrode 215 in the second pixel area PA2 may configure the second light-emitting element LE2.

The capping layer 217 may be located on the opposite electrode 215. The capping layer 217 may include a capping layer opening portion 217OP overlapping the substrate opening portion 100OP in a plan view. The capping layer 217 may include an organic material, an inorganic material, or a mixture thereof. Examples of the organic material may include at least one selected from a group including tris-8-hydroxyquinoline aluminum (Alq3), 2,5-bis(6′-(2′,2″-bipyridyl))-1,1-dimethyl-3,4-diphenylsilole, 4′-bis[N-(1-napthyl)-N-phenyl-amion] biphenyl (α-NPD), N,N′-diphenyl-N,N′-bis(3-methylphenyl)-1,1′-biphenyl-4,4′-diamine (TPD), 1,1′-bis(di-4-tolylaminophenyl) cyclohexane (TAPC), a triaryl amine derivative (EL301), 8-quinolinolato lithium (Liq), N-(diphenyl-4-yl)-9,9-dimethyl-N-(4(9-phenyl-9H-carbazol-3-yl)phenyl)-9H-fluorene-2-amine (HT211), 2-(4-(9,10-di(naphthalene-2-yl)anthracene-2-yl)phenyl)-1-phenyl-1H-benzo-[D]imidazole (LG201). Examples of the inorganic material may include one or more selected from a group including ITO, IZO, SiO₂, SiNₓ, Y₂O₃, WO₃, MoO₃, and Al₂O₃. In some embodiments, the capping layer 217 may include lithium fluoride (LiF). In some embodiments, a first portion of the capping layer 217 may be located on the inner side surface of the first organic substrate layer 100a defining the first organic substrate opening portion 100OPa (e.g., with the first functional layer 212, the second functional layer 214, and the opposite electrode 215 therebetween). A second portion of the capping layer 217 may be located on the inner side surface of the second organic substrate layer 100c defining the second organic substrate opening portion 100OPc (e.g., with the first functional layer 212, the second functional layer 214, and the opposite electrode 215 therebetween). A third portion of the capping layer 217 may be located on the inner side surface of the organic insulating layer OIL defining the organic insulating layer opening portion OILOP (e.g., with the first functional layer 212, the second functional layer 214, and the opposite electrode 215 therebetween).

The encapsulation layer 300 may be located on the light-emitting element layer LEL. Referring to FIG. 7A, the encapsulation layer 300 may include at least one inorganic encapsulation layer and at least one organic encapsulation layer. For example, the encapsulation layer 300 may include the first inorganic encapsulation layer 310, the organic encapsulation layer 320, and the second inorganic encapsulation layer 330, which are sequentially stacked. Referring to FIG. 7B, the encapsulation layer 300 may include at least one inorganic encapsulation layer. For example, the encapsulation layer 300 may include the first inorganic encapsulation layer 310. Hereinafter, a case in which the encapsulation layer 300 includes the first inorganic encapsulation layer 310, the organic encapsulation layer 320, and the second inorganic encapsulation layer 330, which are sequentially stacked, as shown in FIG. 7A will be mainly described in detail.

The first inorganic encapsulation layer 310 may cover the first light-emitting element LE1 and the second light-emitting element LE2. The first inorganic encapsulation layer 310 may extend from the first pixel area PA1 to the second pixel area PA2 across the substrate opening portion 100OP. The first inorganic encapsulation layer 310 may extend from the first pixel area PA1 to the second pixel area PA2 via the opening area OPA. The first inorganic encapsulation layer 310 may extend from the first pixel area PA1 to the opening area OPA, and may extend from the opening area OPA to the second pixel area PA2.

In one or more embodiments, a distance from a lower surface 310S of the first inorganic encapsulation layer 310 to an upper surface of the inorganic layer 118 in a third direction (e.g., z direction) may be about 15 μm, wherein the lower surface 310S overlaps the opening area OPA in a plan view. The lower surface 310S of the first inorganic encapsulation layer 310 may be a surface that is furthest from the second inorganic encapsulation layer 330 in the opening area OPA. The upper surface of the inorganic layer 118 may be a surface facing the first pixel electrode 211A and/or the second pixel electrode 211B.

At least a portion of a lower surface 118LS of the inorganic layer 118 may directly contact the first inorganic encapsulation layer 310. The lower surface 118LS of the inorganic layer 118 may be a surface facing the substrate 100. In this case, penetration of moisture or foreign substances into the first light-emitting element LE1 and/or the second light-emitting element LE2 may be prevented or reduced by the inorganic layer 118 and the first inorganic encapsulation layer 310.

The inorganic insulating layer IIL may directly contact the first inorganic encapsulation layer 310. In this case, penetration of moisture or foreign substances into the first pixel area PA1 and/or the second pixel area PA2 may be prevented or reduced by the inorganic insulating layer IIL and the first inorganic encapsulation layer 310.

At least a portion of a lower surface of the inorganic substrate layer may directly contact the first inorganic encapsulation layer 310. For example, at least a portion of a lower surface 100bLS of the first inorganic substrate layer 100b may directly contact the first inorganic encapsulation layer 310. The lower surface 100bLS of the first inorganic substrate layer 100b may be a surface facing the first organic substrate layer 100a. At least a portion of a lower surface of the second inorganic substrate layer 100d may directly contact the first inorganic encapsulation layer 310. The lower surface of the second inorganic substrate layer 100d may be a surface facing the second organic substrate layer 100c. In this case, penetration of moisture or foreign substances into the first pixel area PA1 and/or the second pixel area PA2 may be prevented or reduced by the inorganic substrate layer and the first inorganic encapsulation layer 310.

The organic encapsulation layer 320 may be located on the first inorganic encapsulation layer 310. The organic encapsulation layer 320 may include the first organic encapsulation portion 320A, the second organic encapsulation portion 320B, and the third encapsulation portion 320C. The first organic encapsulation portion 320A, the second organic encapsulation portion 320B, and the third encapsulation portion 320C may be integrally provided. The first organic encapsulation portion 320A may overlap the first light-emitting element LE1 in a plan view. The second organic encapsulation portion 320B may overlap the second light-emitting element LE2 in a plan view. The third encapsulation portion 320C may overlap the substrate opening portion 100OP in a plan view, and may extend between the first light-emitting element LE1 and the second light-emitting element LE2. The third encapsulation portion 320C may be arranged in the intermediate opening portion 220OPC. The third encapsulation portion 320C may be arranged in the inorganic insulating layer opening portion IlLOP and the organic insulating layer opening portion OILOP. In other words, at least a portion of the organic encapsulation layer 320 may be arranged in the inorganic insulating layer opening portion IlLOP and the organic insulating layer opening portion OILOP. The third encapsulation portion 320C may be arranged in the first organic substrate opening portion 100OPa and the second organic substrate opening portion 100OPc.

The second inorganic encapsulation layer 330 may be located on the organic encapsulation layer 320. In the present embodiments, the substrate 100 may include the opening area OPA having the substrate opening portion 100OP. Accordingly, reduction in light transmittance or sound transmittance by the substrate 100 may be mitigated or prevented. In addition, components of the pixel circuit layer PCL and components of the light-emitting element layer LEL might not be arranged in the opening area OPA. Accordingly, reduction in light transmittance or sound transmittance by the substrate 100 may be mitigated or prevented. In addition, because a large portion of the opening area OPA is arranged with the third encapsulation portion 320C having high light transmittance or sound transmittance, the light transmittance or the sound transmittance of the display panel 10 may be increased in the transmission area TA of FIG. 2.

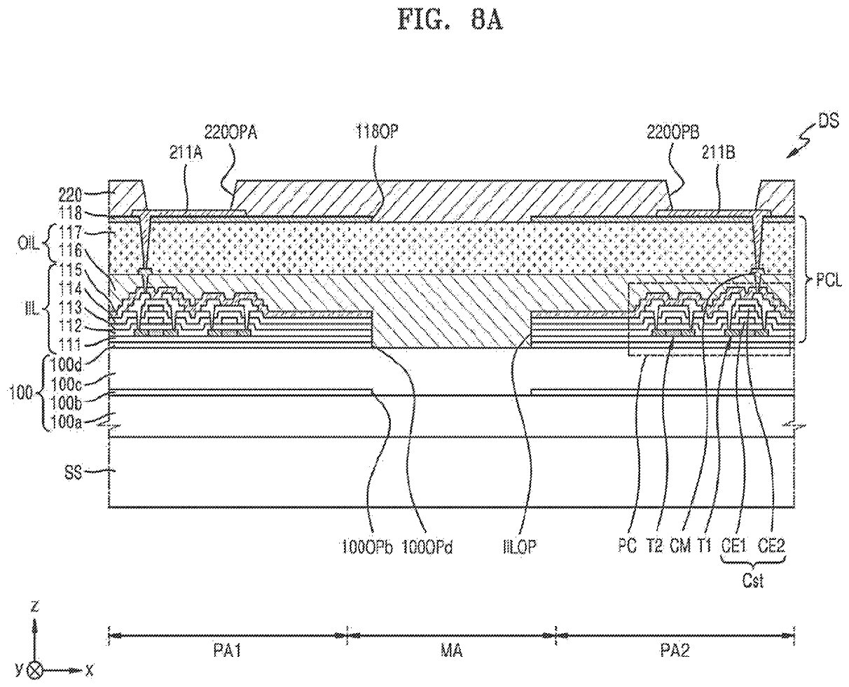

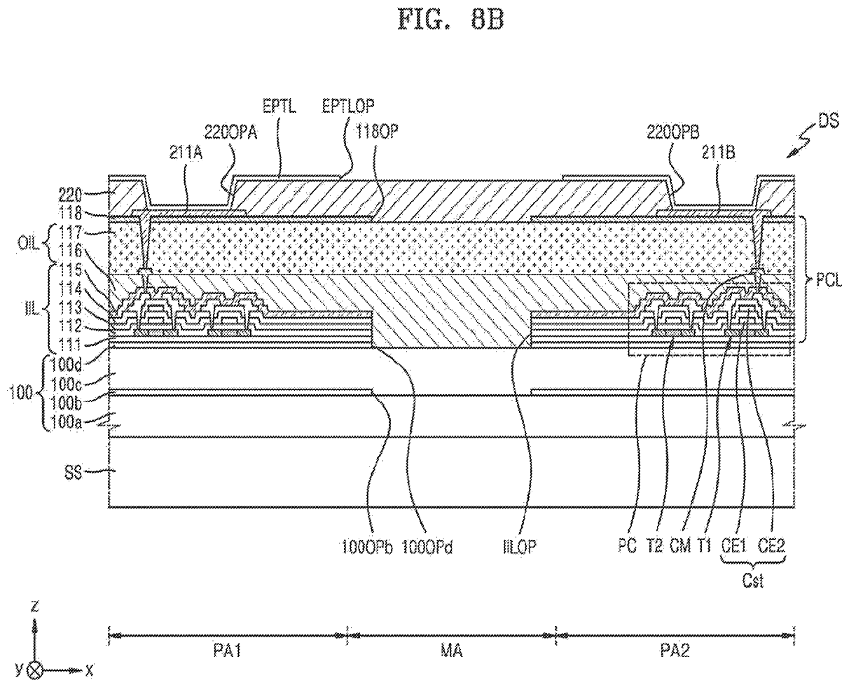

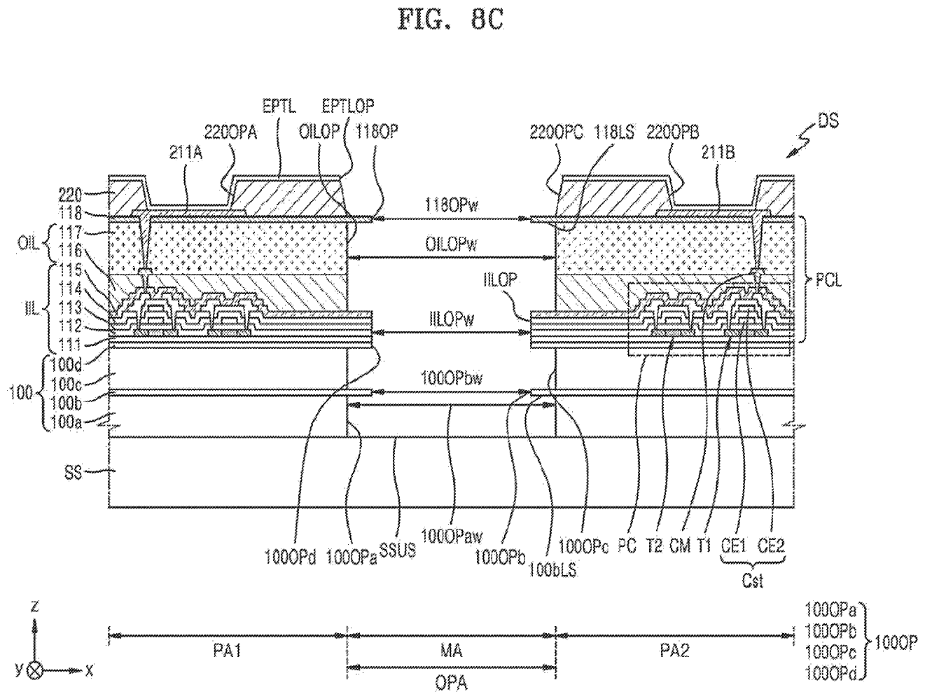

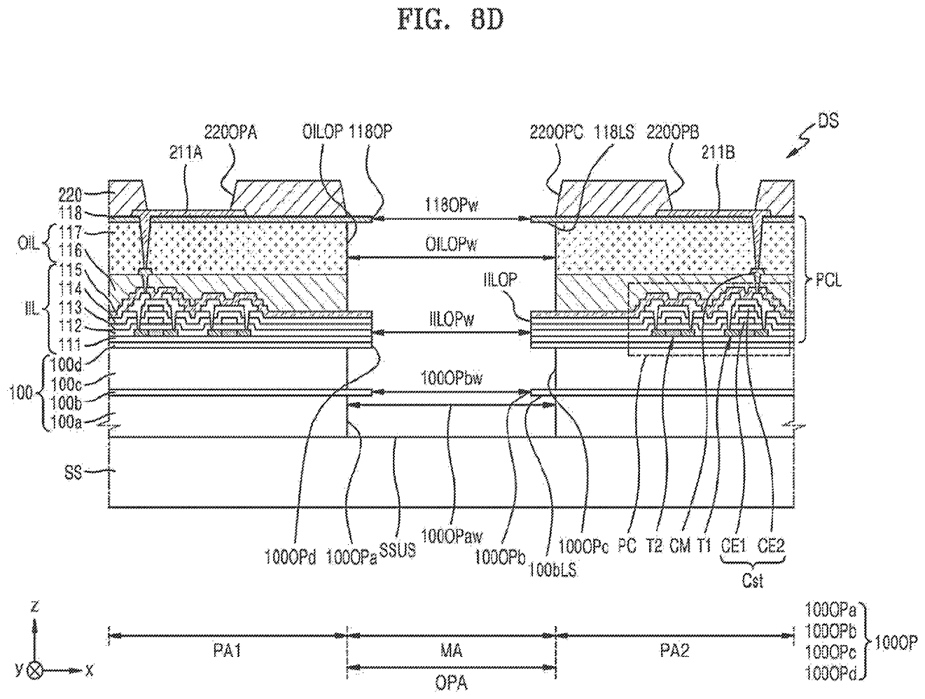

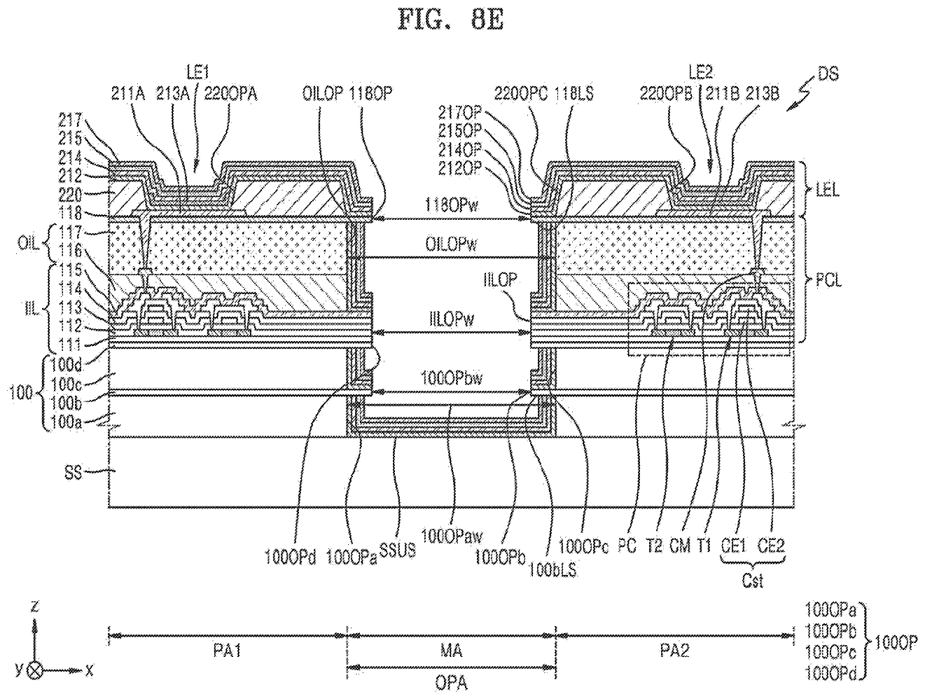

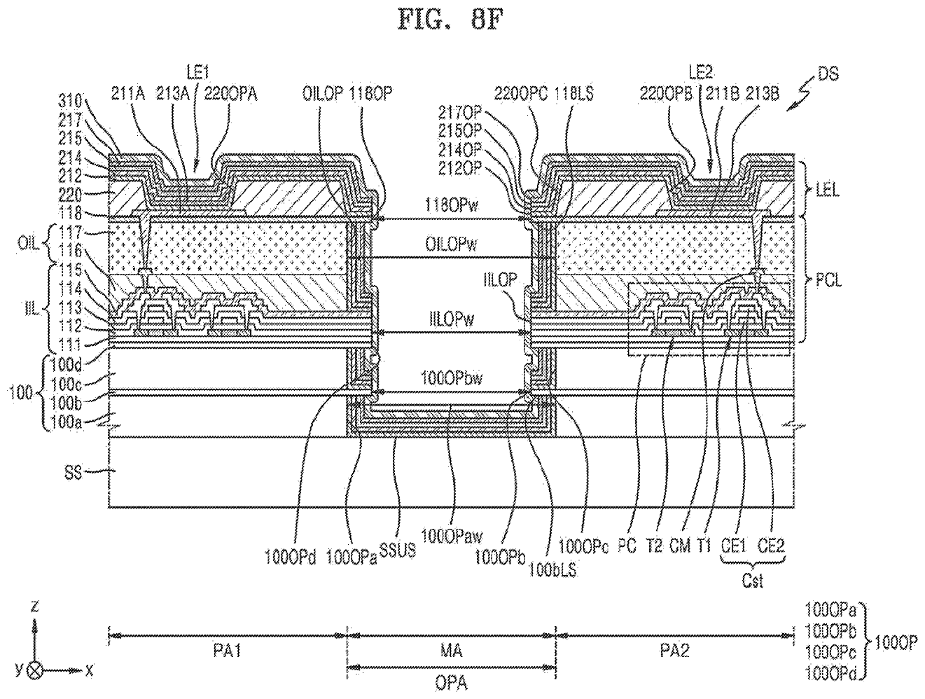

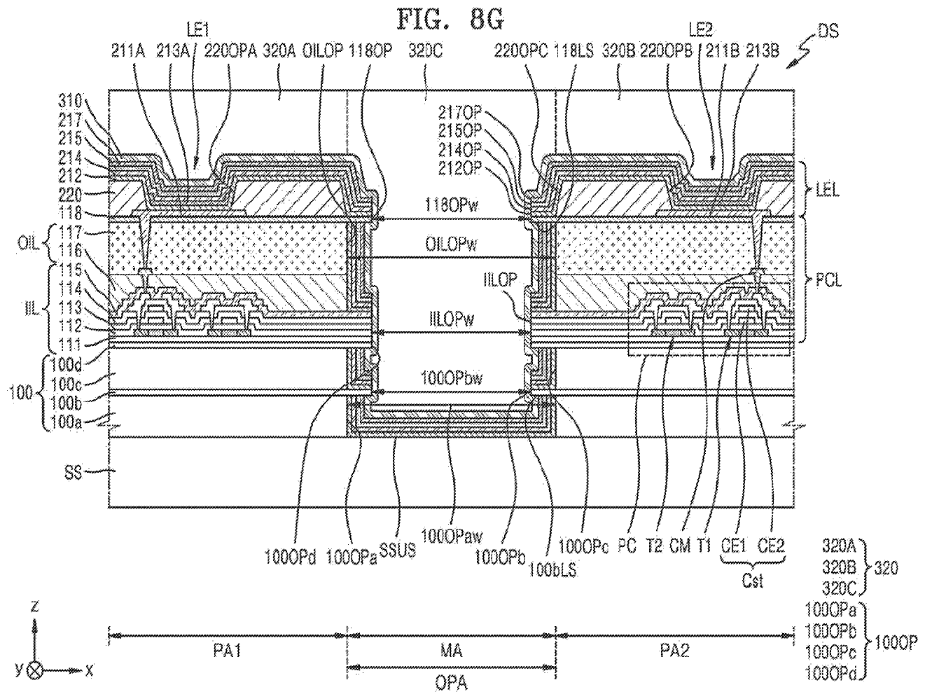

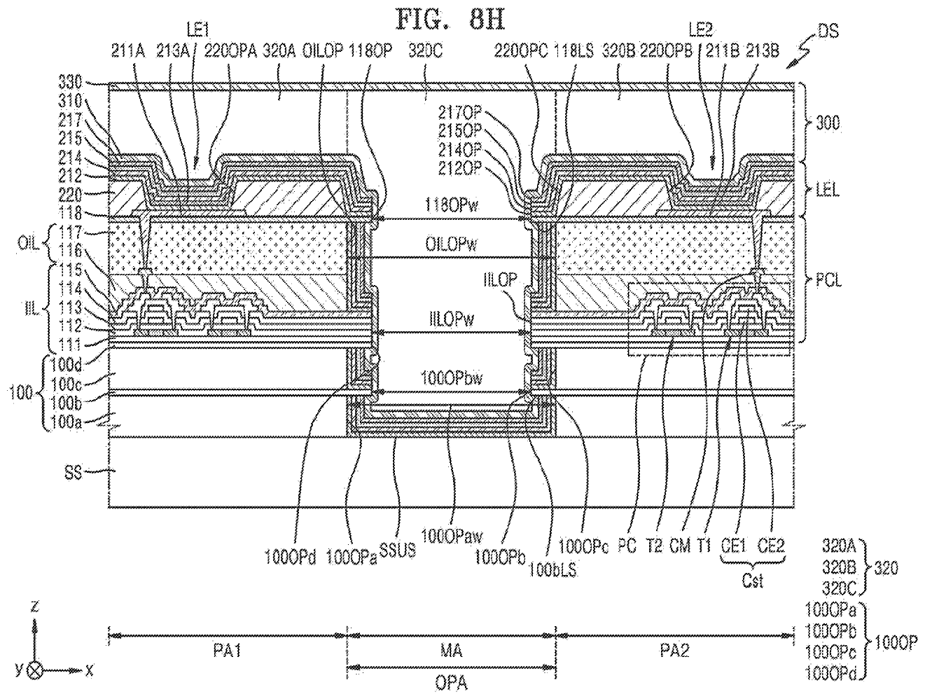

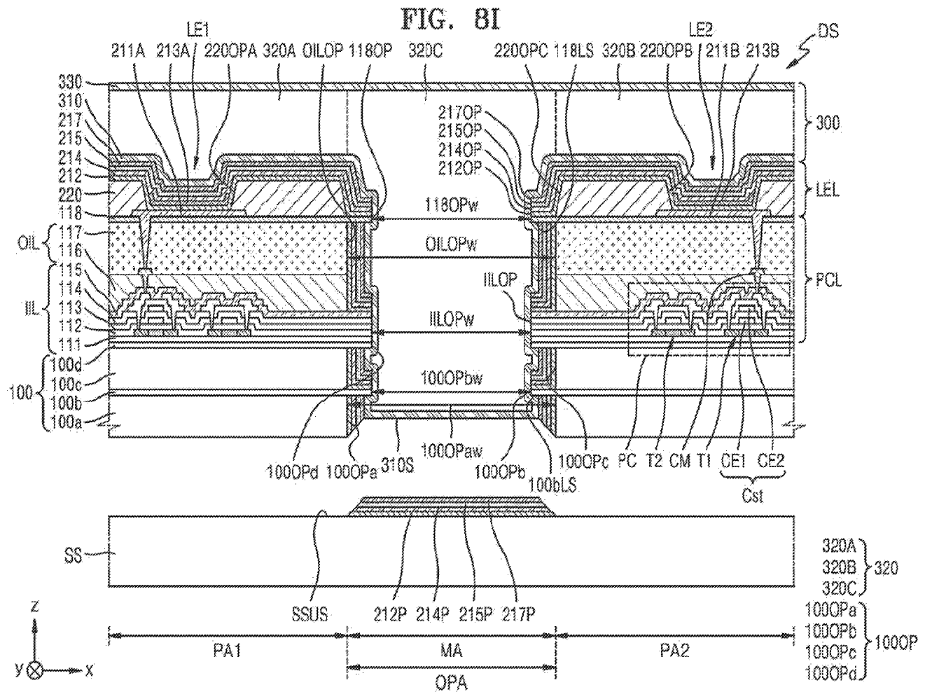

FIGS. 8A to 8I are cross-sectional views schematically illustrating a method of manufacturing a display device according to one or more embodiments. In FIGS. 8A to 8I, the same reference numerals as those in FIG. 7A refer to the same members/components, and redundant descriptions thereof will be omitted.

Referring to FIG. 8A, a display substrate DS may be formed on a support substrate SS. The display substrate DS may be a display device or a display panel. The support substrate SS is a material having hardness and rigidity that may support a display device or a display panel that is being manufactured, and may include, for example, glass.

The display substrate DS may include the substrate 100, the pixel circuit layer PCL, the first pixel electrode 211A, the second pixel electrode 211B, and the pixel defining layer 220. The substrate 100 may include the first pixel area PA1, the second pixel area PA2, and a middle area MA. The middle area MA may be arranged between the first pixel area PA1 and the second pixel area PA2. The substrate 100 may include an organic substrate layer, and an inorganic substrate layer located on the organic substrate layer. In one or more embodiments, the substrate 100 may include the first organic substrate layer 100a, the first inorganic substrate layer 100b, the second organic substrate layer 100c, and the second inorganic substrate layer 100d. The first organic substrate layer 100a, the first inorganic substrate layer 100b, the second organic substrate layer 100c, and the second inorganic substrate layer 100d may be sequentially stacked. In one or more embodiments, the first inorganic substrate layer 100b may have the first inorganic substrate opening portion 100OPb overlapping the middle area MA in a plan view. The second inorganic substrate layer 100d may have the second inorganic substrate opening portion 100OPd overlapping the middle area MA in a plan view. In one or more embodiments, the first organic substrate layer 100a and the second organic substrate layer 100c may continuously extend in the first pixel area PA1, the middle area MA, and the second pixel area PA2.

The pixel circuit layer PCL may be located on the substrate 100. The pixel circuit layer PCL may include the inorganic insulating layer IIL, the pixel circuit PC, the organic insulating layer OIL, the connection electrode CM, and the inorganic layer 118. The inorganic insulating layer IIL may be arranged between the substrate 100 and the light-emitting element layer LEL. The organic insulating layer OIL may be arranged between the inorganic insulating layer IIL and the light-emitting element layer LEL. In one or more embodiments, the organic insulating layer OIL may be between the inorganic insulating layer IIL and the inorganic layer 118. The pixel circuit PC may include the first transistor T1, the second transistor T2, and the storage capacitor Cst. The storage capacitor Cst may include the first capacitor electrode CE1 and the second capacitor electrode CE2.

The inorganic insulating layer IIL may have the inorganic insulating layer opening portion IILOP overlapping the middle area MA in a plan view. In one or more embodiments, the organic insulating layer OIL may continuously extend in the first pixel area PA1, the middle area MA, and the second pixel area PA2. In some embodiments, the organic insulating layer OIL may have an organic insulating layer opening portion overlapping the middle area MA in a plan view. The inorganic layer 118 may have the inorganic layer opening portion 118OP overlapping the middle area MA in a plan view.

The first pixel electrode 211A and the second pixel electrode 211B may be located on the inorganic layer 118 and/or the organic insulating layer OIL. The first pixel electrode 211A may be arranged in the first pixel area PA1. The second pixel electrode 211B may be arranged in the second pixel area PA2. In one or more embodiments, a width of at least one of the first pixel electrode 211A and the second pixel electrode 211B may be about 9 μm to about 30 μm.

The pixel defining layer 220 may cover an edge of the first pixel electrode 211A and an edge of the second pixel electrode 211B. The pixel defining layer 220 may include the first pixel opening portion 220OPA and the second pixel opening portion 220OPB. The first pixel opening portion 220OPA may overlap the first pixel electrode 211A in a plan view. The second pixel opening portion 220OPB may overlap the second pixel electrode 211B in a plan view. In one or more embodiments, the pixel defining layer 220 may extend from the first pixel area PA1 to the middle area MA. The pixel defining layer 220 may extend from the middle area MA to the second pixel area PA2. In some embodiments, the pixel defining layer 220 may have an intermediate opening portion overlapping the middle area MA in a plan view.

Referring to FIGS. 8B to 8D, the opening area OPA including the substrate opening portion 100OP exposing at least a portion of an upper surface SSUS of the support substrate SS may be formed by removing at least a portion of the substrate 100 in the middle area MA.

Referring to FIG. 8B, an etch protection layer EPTL may be formed. The etch protection layer EPTL may be located on the first pixel electrode 211A, the second pixel electrode 211B, and the pixel defining layer 220. The etch protection layer EPTL may have an etch protection layer opening portion EPTLOP overlapping the middle area MA in a plan view. Accordingly, a portion of the pixel defining layer 220 (e.g., a portion overlapping the middle area MA in a plan view) may be exposed through the etch protection layer opening portion EPTLOP.

The etch protection layer opening portion EPTLOP may be formed through a following operation. First, the etch protection layer EPTL may be formed on the first pixel electrode 211A, the second pixel electrode 211B, and the pixel defining layer 220. The etch protection layer EPTL may be formed by using, for example, sputtering. Next, a photoresist pattern may be formed on a portion of the etch protection layer EPTL (e.g., portions overlapping the first pixel area PA1 and the second pixel area PA2 in a plan view). Then, the etch protection layer opening portion EPTLOP may be formed by removing at least a portion of the etch protection layer EPTL (e.g., a portion overlapping the middle area MA in a plan view). The etch protection layer EPTL may include IZO. In one or more embodiments, the etch protection layer opening portion EPTLOP may be formed by wet etching the etch protection layer EPTL.

Referring to FIG. 8C, components overlapping the middle area MA in a plan view may be etched. For example, the first organic substrate layer 100a, the second organic substrate layer 100c, the organic insulating layer OIL, and the pixel defining layer 220 may be etched. The etching may be dry etching. In one or more embodiments, the intermediate opening portion 220OPC overlapping the middle area MA in a plan view may be formed in the pixel defining layer 220. In one or more embodiments, a distance from the first pixel opening portion 220OPA to the intermediate opening portion 220OPC in a first direction (e.g., x direction) may be about 8 μm. In one or more embodiments, a distance between the second pixel opening portion 220OPB to the intermediate opening portion 220OPC in the first direction (e.g., x direction) may be about 8 μm.

The organic insulating layer OIL may be over-etched. The organic insulating layer opening portion OILOP overlapping the middle area MA in a plan view may be formed in the organic insulating layer OIL. The width OILOPw of the organic insulating layer opening portion OILOP may be greater than the width 118OPw of the inorganic layer opening portion 118OP. In one or more embodiments, the width 118OPw of the inorganic layer opening portion 118OP may be about 10 μm to about 80 μm. The inorganic layer 118 may protrude from the first pixel area PA1 or the second pixel area PA2 to the opening area OPA. The inorganic layer 118 may have one or more protruding tips protruding toward the center of the opening area OPA. In this case, at least a portion of the lower surface 118LS of the inorganic layer 118 may be exposed. The lower surface 118LS of the inorganic layer 118 may be a surface facing the substrate 100. The width OILOPw of the organic insulating layer opening portion OILOP may be greater than the width IILOPw of the inorganic insulating layer opening portion IlLOP. In this case, at least a portion of an upper surface of the inorganic insulating layer IIL may be exposed.

The organic substrate layer may be over-etched. An organic substrate opening portion having a greater width than that of an inorganic substrate opening portion may be formed in the organic substrate layer. For example, the second organic substrate layer 100c may be over-etched. The second organic substrate opening portion 100OPc may be formed in the second organic substrate layer 100c. A width of the second organic substrate opening portion 100OPc may be greater than a width of the second inorganic substrate opening portion 100OPd. The second inorganic substrate layer 100d and the inorganic insulating layer IIL may protrude from the first pixel area PA1 or the second pixel area PA2 to the opening area OPA. The second inorganic substrate layer 100d and the inorganic insulating layer IIL may each have one or more protruding tips protruding toward the center of the opening area OPA. In this case, at least a portion of the lower surface of the second inorganic substrate layer 100d may be exposed. The lower surface of the second inorganic substrate layer 100d may be a surface facing the second organic substrate layer 100c. In addition, the first organic substrate opening portion 100OPa may be formed in the first organic substrate layer 100a. The width 100OPaw of the first organic substrate opening portion 100OPa may be greater than the width 100OPbw of the first inorganic substrate opening portion 100OPb. The first inorganic substrate layer 100b may protrude from the first pixel area PA1 or the second pixel area PA2 to the opening area OPA. The first inorganic substrate layer 100b may have one or more protruding tips protruding toward the center of the opening area OPA. In this case, at least a portion of a lower surface 100bLS of the first inorganic substrate layer 100b may be exposed. The lower surface 100bLS of the first inorganic substrate layer 100b may be a surface facing the first organic substrate layer 100a.

The first organic substrate opening portion 100OPa, the first inorganic substrate opening portion 100OPb, the second organic substrate opening portion 100OPc, and the second inorganic substrate opening portion 100OPd may be included in the substrate opening portion 100OP. The substrate opening portion 100OP may expose at least a portion of the upper surface SSUS of the support substrate SS.

Referring to FIG. 8D, the etch protection layer EPTL may be removed. The etch protection layer EPTL may be removed by wet etching. Unlike the present embodiments, when a laser beam is irradiated to the middle area MA to form the opening area OPA, the deviation due to a laser operation may be about 50 μm or more. Accordingly, the opening area OPA may not be precisely formed. In the present embodiments, because the opening area OPA is formed through an etching operation, the opening area OPA may be precisely formed. For example, the width 118OPw of the inorganic layer opening portion 118OP may be about 10 μm to about 80 μm.

Referring to FIG. 8E, the first functional layer 212 may be formed. The first functional layer 212 may have the first functional layer opening portion 212OP overlapping the substrate opening portion 100OP in a plan view. A first portion of the first functional layer 212 may be formed on the inner side surface of the first organic substrate layer 100a defining the first organic substrate opening portion 100OPa. A second portion of the first functional layer 212 may be formed on the inner side surface of the second organic substrate layer 100c defining the second organic substrate opening portion 100OPc. A third portion of the first functional layer 212 may be formed on the inner side surface of the organic insulating layer OIL defining the organic insulating layer opening portion OILOP. A portion of the first functional layer 212 may be formed on (e.g., above) at least a portion of the upper surface SSUS of the support substrate SS exposed by the substrate opening portion 100OP.

The first emission layer 213A and the second emission layer 213B may be formed on the first functional layer 212. The first emission layer 213A may be formed on the first pixel electrode 211A. The second emission layer 213B may be formed on the second pixel electrode 211B.

The second functional layer 214 may be formed on the first emission layer 213A, the second emission layer 213B, and the first functional layer 212. The second functional layer 214 may have the second functional layer opening portion 214OP overlapping the substrate opening portion 100OP in a plan view. A first portion of the second functional layer 214 may be formed on the inner side surface of the first organic substrate layer 100a defining the first organic substrate opening portion 100OPa. A second portion of the second functional layer 214 may be formed on the inner side surface of the second organic substrate layer 100c defining the second organic substrate opening portion 100OPc. A third portion of the second functional layer 214 may be formed on the inner side surface of the organic insulating layer OIL defining the organic insulating layer opening portion OILOP. A portion of the second functional layer 214 may be formed on (e.g., above) at least a portion of the upper surface SSUS of the support substrate SS exposed by the substrate opening portion 100OP. A portion of the second functional layer 214 may be formed on a portion of the first functional layer 212 in the opening area OPA.

The opposite electrode 215 may be formed on the second functional layer 214. The opposite electrode 215 may be formed on the first emission layer 213A and the second emission layer 213B. The opposite electrode 215 may have the opposite electrode opening portion 215OP overlapping the substrate opening portion 100OP in a plan view. A first portion of the opposite electrode 215 may be formed on the inner side surface of the first organic substrate layer 100a defining the first organic substrate opening portion 100OPa. A second portion of the opposite electrode 215 may be formed on the inner side surface of the second organic substrate layer 100c defining the second organic substrate opening portion 100OPc. A third portion of the opposite electrode 215 may be formed on the inner side surface of the organic insulating layer OIL defining the organic insulating layer opening portion OILOP. A portion of the opposite electrode 215 may be formed on (e.g., above) at least a portion of the upper surface SSUS of the support substrate SS exposed by the substrate opening portion 100OP. A portion of the opposite electrode 215 may be formed on a portion of the second functional layer 214 in the opening area OPA.

The capping layer 217 may be formed on the opposite electrode 215. The capping layer 217 may include the capping layer opening portion 217OP overlapping the substrate opening portion 100OP in a plan view. A first portion of the capping layer 217 may be on the inner side surface of the first organic substrate layer 100a defining the first organic substrate opening portion 100OPa. A second portion of the capping layer 217 may be on the inner side surface of the second organic substrate layer 100c defining the second organic substrate opening portion 100OPc. A third portion of the capping layer 217 may be on the inner side surface of the organic insulating layer OIL defining the organic insulating layer opening portion OILOP. A portion of the capping layer 217 may be formed on (e.g., above) at least a portion of the upper surface SSUS of the support substrate SS exposed by the substrate opening portion 100OP. A portion of the capping layer 217 may be formed on a portion of the opposite electrode 215 in the opening area OPA.

Referring to FIGS. 8F to 8H, the encapsulation layer 300 may be formed on the capping layer 217. In one or more embodiments, the encapsulation layer 300 may include at least one inorganic encapsulation layer. For example, the encapsulation layer 300 may include the first inorganic encapsulation layer 310. In one or more embodiments, the encapsulation layer 300 may include at least one inorganic encapsulation layer and at least one organic encapsulation layer. In one or more embodiments, the encapsulation layer 300 may include the first inorganic encapsulation layer 310, the organic encapsulation layer 320, and the second inorganic encapsulation layer 330, which are sequentially stacked.

Referring to FIG. 8F, the first inorganic encapsulation layer 310 may be formed on the capping layer 217. The first inorganic encapsulation layer 310 may extend from the first pixel area PA1 to the second pixel area PA2 across the substrate opening portion 100OP. The first inorganic encapsulation layer 310 may extend from the first pixel area PA1 to the second pixel area PA2 via the opening area OPA. The first inorganic encapsulation layer 310 may extend from the first pixel area PA1 to the opening area OPA, and may extend from the opening area OPA to the second pixel area PA2.

The first inorganic encapsulation layer 310 may be formed to directly contact at least a portion of the lower surface 118LS of the inorganic layer 118. The lower surface 118LS of the inorganic layer 118 may be a surface facing the substrate 100. In this case, penetration of moisture or foreign substances into the first light-emitting element LE1 and/or the second light-emitting element LE2 may be prevented or reduced by the inorganic layer 118 and the first inorganic encapsulation layer 310.

The first inorganic encapsulation layer 310 may be formed to directly contact the inorganic insulating layer IIL. In this case, penetration of moisture or foreign substances into the first pixel area PA1 and/or the second pixel area PA2 may be prevented or reduced by the inorganic insulating layer IIL and the first inorganic encapsulation layer 310.

The first inorganic encapsulation layer 310 may be formed to directly contact at least a portion of a lower surface of an inorganic substrate layer. For example, the first inorganic encapsulation layer 310 may be formed to directly contact at least a portion of the lower surface 100bLS of the first inorganic substrate layer 100b. The lower surface 100bLS of the first inorganic substrate layer 100b may be a surface facing the first organic substrate layer 100a. The first inorganic encapsulation layer 310 may be formed to directly contact at least a portion of a lower surface of the second inorganic substrate layer 100d. The lower surface of the second inorganic substrate layer 100d may be a surface facing the second organic substrate layer 100c. In this case, penetration of moisture or foreign substances into the first pixel area PA1 and/or the second pixel area PA2 may be prevented or reduced by the inorganic substrate layer and the first inorganic encapsulation layer 310.

The first inorganic encapsulation layer 310 may be formed on (e.g., above) at least a portion of the capping layer 217 in the opening area OPA. The first inorganic encapsulation layer 310 may extend in a direction from the first pixel area PA1 to the second pixel area PA2 in the opening area OPA.

Referring to FIG. 8G, the organic encapsulation layer 320 may be formed on the first inorganic encapsulation layer 310. The organic encapsulation layer 320 may include the first organic encapsulation portion 320A, the second organic encapsulation portion 320B, and the third encapsulation portion 320C. The first organic encapsulation portion 320A, the second organic encapsulation portion 320B, and the third encapsulation portion 320C may be integrally provided. The first organic encapsulation portion 320A may overlap the first light-emitting element LE1 in a plan view. The second organic encapsulation portion 320B may overlap the second light-emitting element LE2 in a plan view. The third encapsulation portion 320C may overlap the substrate opening portion 100OP in a plan view, and may extend between the first light-emitting element LE1 and the second light-emitting element LE2. The third encapsulation portion 320C may be formed in the intermediate opening portion 220OPC. The third encapsulation portion 320C may be formed in the inorganic insulating layer opening portion IILOP and the organic insulating layer opening portion OILOP. In other words, at least a portion of the organic encapsulation layer 320 may be formed in the inorganic insulating layer opening portion IlLOP and the organic insulating layer opening portion OILOP. The third encapsulation portion 320C may be formed in the first organic substrate opening portion 100OPa and the second organic substrate opening portion 100OPc.

Referring to FIG. 8H, the second inorganic encapsulation layer 330 may be formed on the organic encapsulation layer 320. In the present embodiments, the opening area OPA having the substrate opening portion 100OP may be formed in the substrate 100. Accordingly, reduction in light transmittance or sound transmittance by the substrate 100 may be reduced or prevented. In addition, components of the pixel circuit layer PCL and components of the light-emitting element layer LEL may not be arranged in the opening area OPA. Accordingly, reduction in light transmittance or sound transmittance by the substrate 100 may be mitigated or prevented. In addition, because a large portion of the opening area OPA is arranged with the third encapsulation portion 320C having high light transmittance or sound transmittance, the light transmittance or the sound transmittance of the display panel 10 may be increased in the transmission area TA of FIG. 2.

Referring to FIG. 8I, the substrate 100 may be separated from the support substrate SS. In one or more embodiments, the substrate 100 may be detached from the support substrate SS through a laser release method of irradiating a laser beam to the substrate 100. The laser beam may be irradiated in a direction from a lower surface of the support substrate SS to the upper surface SSUS of the support substrate SS. The lower surface of the support substrate SS may be a surface opposite to the upper surface SSUS of the support substrate SS. The laser beam may be irradiated toward a lower surface of the substrate 100, the lower surface facing the upper surface SSUS of the support substrate SS. The laser beam may be formed from, for example, an excimer laser having a wavelength of about 308 nm, a solid-state ultraviolet (UV) laser having a wavelength of about 343 nm or a wavelength of about 355 nm, or the like.

When the substrate 100 is separated from the support substrate SS, the first inorganic encapsulation layer 310 and a portion of the capping layer 217 may be separated from each other in the opening area OPA. In this case, the lower surface 310S of the first inorganic encapsulation layer 310 may be exposed in the opening area OPA. Because an interfacial adhesive force between the first inorganic encapsulation layer 310 and the capping layer 217 is less than an interfacial adhesive force between the capping layer 217 and the opposite electrode 215, the first inorganic encapsulation layer 310 may be separated from a portion of the capping layer 217 without damage. Accordingly, the first inorganic encapsulation layer 310 may extend from the first pixel area PA1 to the second pixel area PA2 across the substrate opening portion 100OP.

In one or more embodiments, a distance from the lower surface 310S of the first inorganic encapsulation layer 310 to an upper surface of the inorganic layer 118 in a third direction (e.g., z direction) may be about 15 μm, wherein the lower surface 310S overlaps the opening area OPA in a plan view.

In the opening area OPA, a portion of the first functional layer 212, that is, a first functional layer pattern 212P including the same material as that of the first functional layer 212, may remain on the upper surface SSUS of the support substrate SS. In the opening area OPA, a portion of the second functional layer 214, that is, a second functional layer pattern 214P including the same material as that of the second functional layer 214, may remain on the upper surface SSUS of the support substrate SS (e.g., with the first functional layer pattern 212P therebetween). In the opening area OPA, a portion of the opposite electrode 215, that is, an opposite electrode pattern 215P including the same material as that of the opposite electrode 215, may remain on the upper surface SSUS of the support substrate SS (e.g., with the first functional layer pattern 212P and the second functional layer pattern 214P therebetween). In the opening area OPA, a portion of the capping layer 217, that is, a capping layer pattern 217P including the same material as that of the capping layer 217, may remain on the upper surface SSUS of the support substrate SS (e.g., with the first functional layer pattern 212P, the second functional layer pattern 214P, and the opposite electrode pattern 215P therebetween). Accordingly, the first functional layer pattern 212P, the second functional layer pattern 214P, the opposite electrode pattern 215P, and the capping layer pattern 217P remaining in the opening area OPA may be removed from the display substrate DS without an additional operation. In this case, the light transmittance or sound transmittance of the display panel may be increased in the opening area OPA of a manufactured display panel.

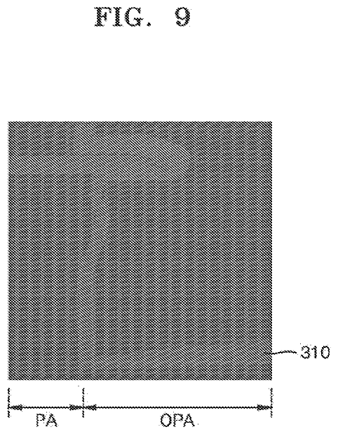

FIG. 9 shows an experimental result showing a portion of the first inorganic encapsulation layer 310 in the opening area OPA and the pixel area PA. FIG. 9 shows an experimental result showing a portion of a display panel or display device manufactured according to the embodiments described with reference to FIGS. 8A to 81.

Referring to FIG. 9, as described with reference to FIG. 81, it may be confirmed that the first inorganic encapsulation layer 310 is not damaged such as cracks even when a substrate is separated from a support substrate. Accordingly, penetration of foreign substances such as moisture into the pixel area PA of the manufactured display panel or display device may be prevented or reduced.

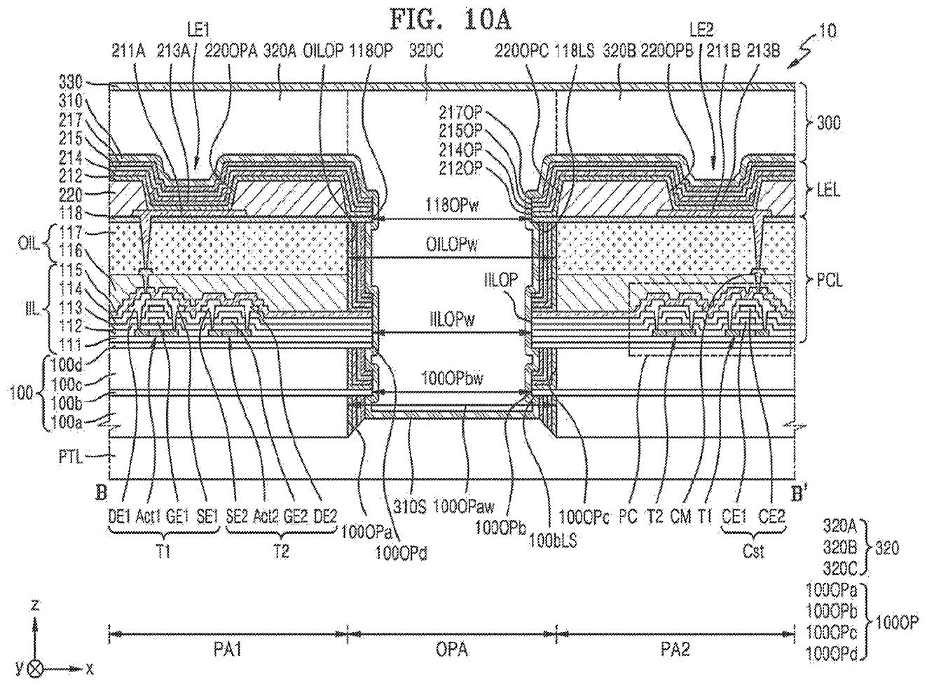

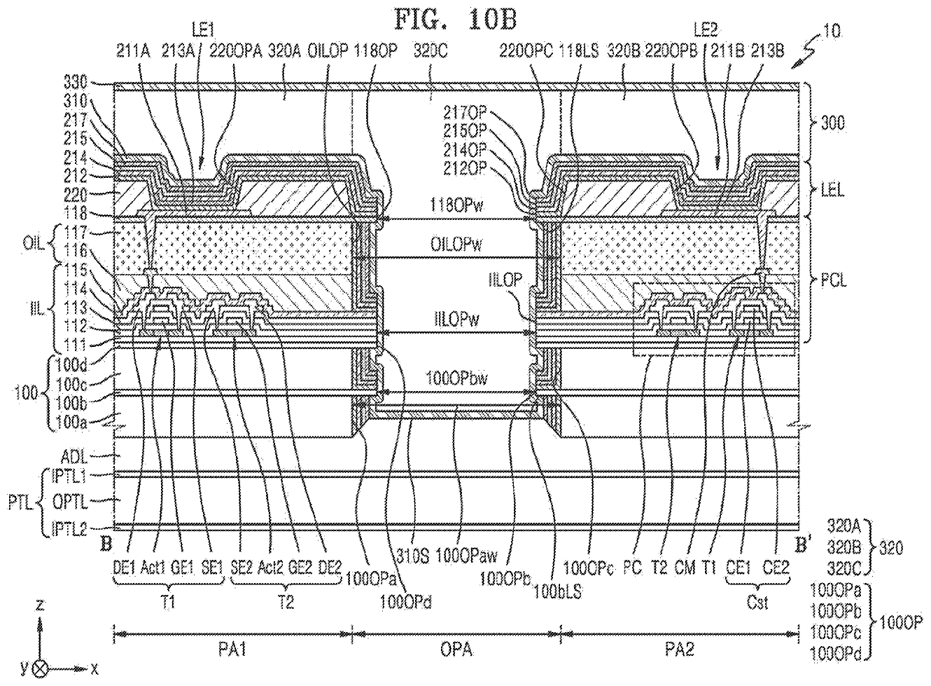

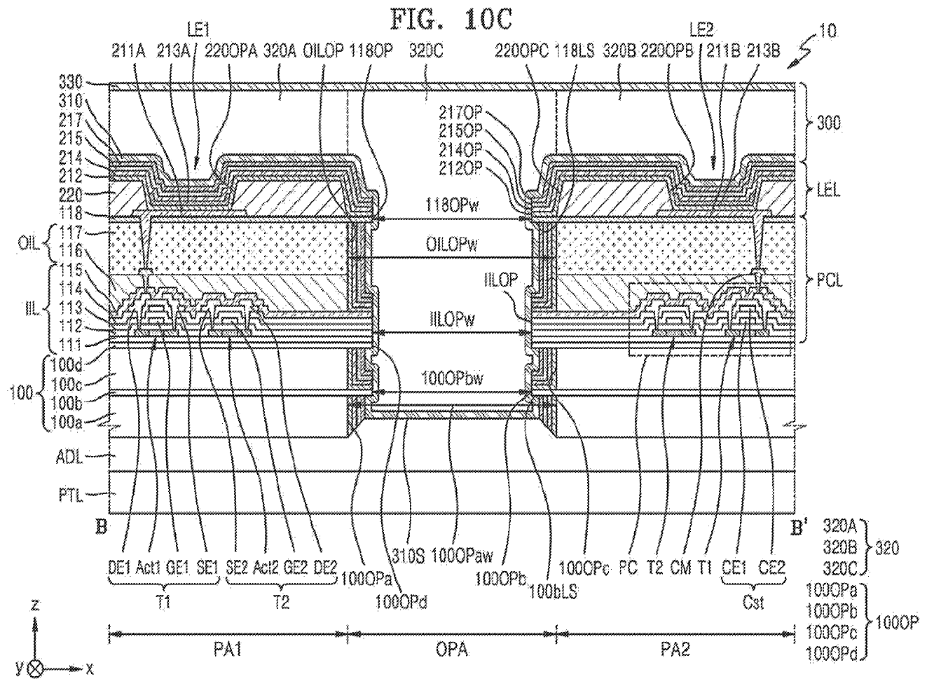

FIGS. 10A to 10C are cross-sectional views each schematically illustrating the display panel 10 taken along the line B-B′ of FIG. 5, according to one or more other embodiments. In FIGS. 10A to 10C, the same reference numerals as those in FIG. 7A refer to the same members/components, and redundant descriptions thereof will be omitted.

Referring to FIG. 10A, the display panel 10 may include the substrate 100, the pixel circuit layer PCL, the light-emitting element layer LEL, the encapsulation layer 300, and a protective layer PTL. The protective layer PTL may be located below the substrate 100. For example, in the opening area OPA, the first inorganic encapsulation layer 310 may be arranged between the organic encapsulation layer 320 and the protective layer PTL. Although FIG. 10A illustrates that the protective layer PTL is entirely arranged in the first pixel area PA1, the opening area OPA, and the second pixel area PA2, in one or more other embodiments, the protective layer PTL may be arranged only in the opening area OPA. The protective layer PTL may include at least one of glass, an organic protective layer including an organic material, and an inorganic protective layer including an inorganic material. In one or more embodiments, the protective layer PTL may include a resin. The protective layer PTL may be formed by an inkjet operation. Damage, such as cracks, of the first inorganic encapsulation layer 310 in the opening area OPA may be prevented or reduced by the protective layer PTL.

Referring to FIGS. 10B and 10C, the display panel 10 may include the substrate 100, the pixel circuit layer PCL, the light-emitting element layer LEL, the encapsulation layer 300, an adhesive layer ADL, and the protective layer PTL. The adhesive layer ADL may be arranged between the substrate 100 and the protective layer PTL. The adhesive layer ADL may include an optically clear adhesive. The protective layer PTL may be located below the substrate 100. The protective layer PTL may include at least one of glass, an organic protective layer including an organic material, and an inorganic protective layer including an inorganic material.

Referring to FIG. 10B, the protective layer PTL may include at least one inorganic protective layer and at least one organic protective layer. The at least one inorganic protective layer may include at least one inorganic material from among aluminum oxide (Al₂O₃), titanium oxide (TiO₂), tantalum oxide (Ta₂O₅), zinc oxide (ZnOₓ), silicon oxide (SiO₂), silicon nitride (SiNₓ), and silicon oxynitride (SiOₓN_{y}). The zinc oxide (ZnOₓ) may be zinc oxide (ZnO) and/or zinc peroxide (ZnO₂). The at least one organic protective layer may include a polymer-based material. The polymer-based material may include an acrylic resin, an epoxy resin, polyimide, polyethylene, or the like. As one or more embodiments, the at least one organic protective layer may include acrylate. In one or more embodiments, the protective layer PTL may include a first inorganic protective layer IPTL1, an organic protective layer OPTL, and a second inorganic protective layer IPTL2, which are sequentially stacked. Damage, such as cracks, of the first inorganic encapsulation layer 310 in the opening area OPA may be prevented or reduced by the protective layer PTL.

In some embodiments, the protective layer PTL may include a first protective layer and a second protective layer. The first protective layer may include a resin, as described with reference to FIG. 10A. The second protective layer may include at least one inorganic protective layer and at least one organic protective layer, as described with reference to FIG. 10B.

Referring to FIG. 10C, the protective layer PTL may include glass. In one or more embodiments, the protective layer PTL may be ultra-thin glass. Damage, such as cracks, of the first inorganic encapsulation layer 310 in the opening area OPA may be prevented or reduced by the protective layer PTL.

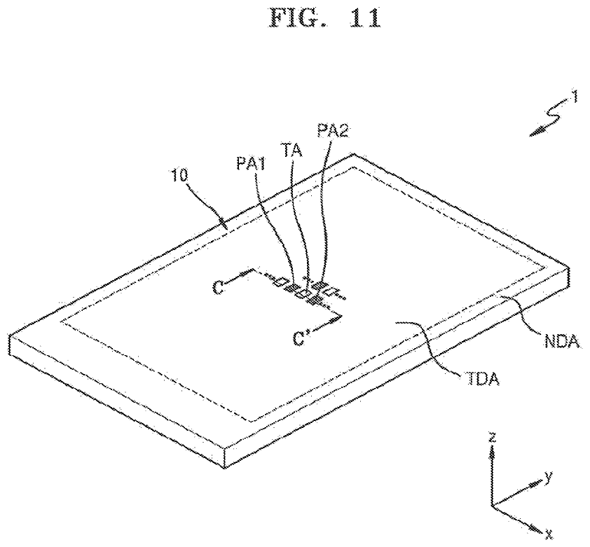

FIG. 11 is a schematic perspective view of the display device 1 according to one or more other embodiments. In FIG. 11, the same reference numerals as those in FIG. 1A refer to the same members/components, and redundant descriptions thereof will be omitted.

Referring to FIG. 11, the display device 1 may include the display panel 10. The display panel 10 may include the transmissive display area TDA and the non-display area NDA. The display device 1 may display an image in the transmissive display area TDA. The transmissive display area TDA may include the first pixel area PA1, the second pixel area PA2, and the transmission area TA. Each of the first pixel area PA1 and the second pixel area PA2 may be provided in plurality. Accordingly, the display panel 10 may have high light transmittance or sound transmittance in the transmissive display area TDA.

The display device 1 may not display an image in the non-display area NDA. The non-display area NDA may be adjacent to the transmissive display area TDA and/or the display area DA in FIG. 3. In one or more embodiments, the non-display area NDA may entirely surround the transmissive display area TDA and/or the display area DA.

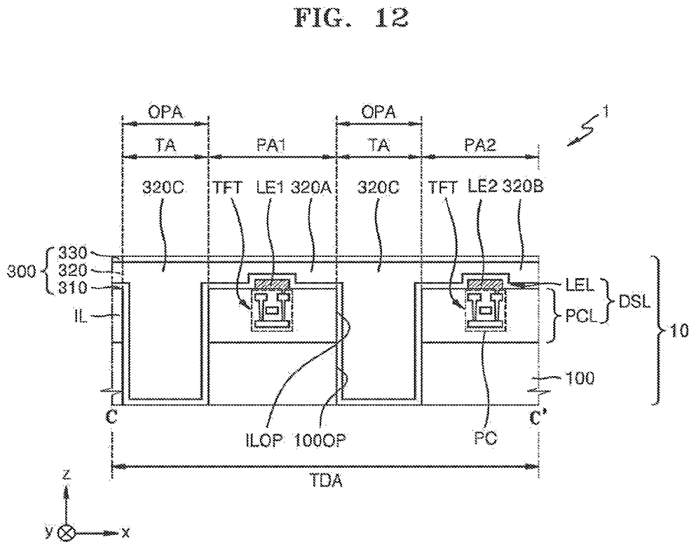

FIG. 12 is a cross-sectional view schematically illustrating the display device 1 taken along the line C-C′ of FIG. 11, according to one or more embodiments. In FIG. 12, the same reference numerals as those in FIG. 2 refer to the same members/components, and redundant descriptions thereof will be omitted.

Referring to FIG. 12, the display device 1 may include the display panel 10. The display panel 10 may include the substrate 100, the display layer DSL, and the encapsulation layer 300. Areas of the display panel 10 may be defined in the substrate 100 and/or a multi-layered film. For example, the transmissive display area TDA may be defined in the substrate 100. The transmissive display area TDA may include the first pixel area PA1, the second pixel area PA2, and the transmission area TA.

The transmission area TA may be between the first pixel area PA1 and the second pixel area PA2. The transmission area TA may include the opening area OPA having the substrate opening portion 100OP. As the transmission area TA includes the opening area OPA, the light transmittance or sound transmittance of the display panel 10 may be increased.

The display layer DSL may be located on the substrate 100. The display layer DSL may include the pixel circuit layer PCL and the light-emitting element layer LEL. The pixel circuit layer PCL may include the insulating layer IL and the pixel circuit PC. The insulating layer IL may include the insulating layer opening ILOP overlapping the substrate opening portion 100OP in a plan view. The insulating layer opening ILOP may be connected to the substrate opening portion 100OP. Accordingly, the light transmittance or sound transmittance of the display panel 10 may be increased in the opening area OPA. The pixel circuit PC may be inserted into the insulating layer IL.

The light-emitting element layer LEL may be located on the pixel circuit layer PCL. The light-emitting element layer LEL may include a light-emitting element. In one or more embodiments, the light-emitting element layer LEL may include the first light-emitting element LE1 and the second light-emitting element LE2. The first light-emitting element LE1 may be arranged in the first pixel area PA1. The second light-emitting element LE2 may be arranged in the second pixel area PA2.

The encapsulation layer 300 may be located on the display layer DSL. The encapsulation layer 300 may be located on the light-emitting element layer LEL. In one or more embodiments, the encapsulation layer 300 may include at least one inorganic encapsulation layer. For example, the encapsulation layer 300 may include the first inorganic encapsulation layer 310. In one or more embodiments, the encapsulation layer 300 may include at least one inorganic encapsulation layer and at least one organic encapsulation layer. In one or more embodiments, the encapsulation layer 300 may include the first inorganic encapsulation layer 310, the organic encapsulation layer 320, and the second inorganic encapsulation layer 330, which are sequentially stacked. The first inorganic encapsulation layer 310 may cover the first light-emitting element LE1 and the second light-emitting element LE2. The first inorganic encapsulation layer 310 may extend from the first pixel area PA1 to the second pixel area PA2 across the substrate opening portion 100OP. The first inorganic encapsulation layer 310 may prevent or reduce penetration of moisture or foreign substances from the opening area OPA into the light-emitting element layer LEL.

The organic encapsulation layer 320 may be located on the first inorganic encapsulation layer 310. The organic encapsulation layer 320 may include the first organic encapsulation portion 320A, the second organic encapsulation portion 320B, and the third encapsulation portion 320C. The first organic encapsulation portion 320A, the second organic encapsulation portion 320B, and the third encapsulation portion 320C may be integrally provided. The first organic encapsulation portion 320A may overlap the first light-emitting element LE1 in a plan view. The second organic encapsulation portion 320B may overlap the second light-emitting element LE2 in a plan view. The third encapsulation portion 320C may overlap the substrate opening portion 100OP in a plan view, and may extend between the first light-emitting element LE1 and the second light-emitting element LE2. The third encapsulation portion 320C may be arranged in the substrate opening portion 100OP and the insulating layer opening ILOP. In the present embodiments, the substrate 100 may include the opening area OPA to reduce or prevent reduction of the light transmittance or sound transmittance due to the substrate 100. Because a large portion of the opening area OPA is arranged with the third encapsulation portion 320C having high light transmittance or sound transmittance, the light transmittance or sound transmittance of the display panel 10 may be increased in the transmission area TA. The second inorganic encapsulation layer 330 may be located on the organic encapsulation layer 320.

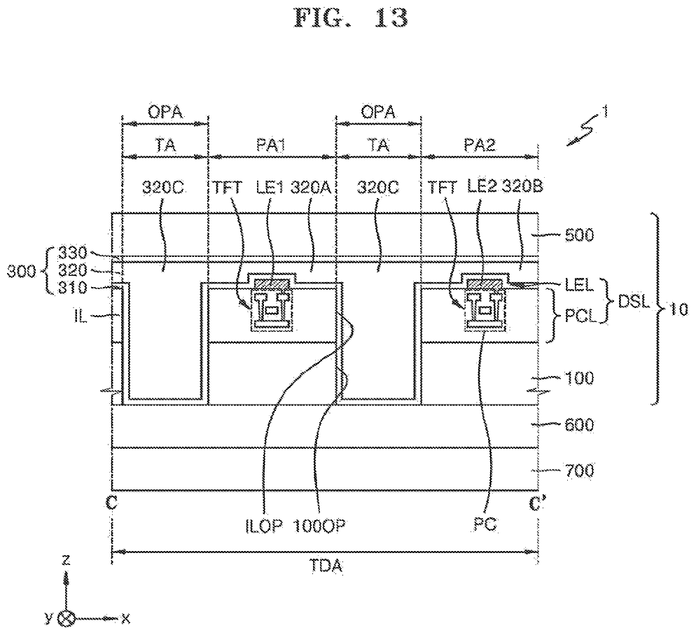

FIG. 13 is a cross-sectional view schematically illustrating the display device 1 taken along the line C-C′ of FIG. 11, according to one or more embodiments. In FIG. 13, the same reference numerals as those in FIG. 12 refer to the same members/components, and redundant descriptions thereof will be omitted.

Referring to FIG. 13, the display device 1 may include the display panel 10, a light compensation layer 600, and a light reflection layer 700. The display panel 10 may include the substrate 100, the display layer DSL, the encapsulation layer 300, and the anti-reflection layer 500.

The anti-reflection layer 500 may be located on the encapsulation layer 300. In one or more embodiments, the anti-reflection layer 500 may be located on (e.g., above) the first inorganic encapsulation layer 310. The anti-reflection layer 500 may reduce the reflectance of light (e.g., external light) incident toward the display device 1. The anti-reflection layer 500 may include a first circular polarization layer including a first circular polarizer. The first circular polarization layer may include a first retarder and a first polarizer. The first retarder may include a λ/2 retarder and/or a λ/4 retarder.

The light reflection layer 700 may be located below the substrate 100. The light reflection layer 700 may reflect light. The light reflection layer 700 may function as a mirror. In one or more embodiments, the light reflection layer 700 may include Ag.

The light compensation layer 600 may be arranged between the substrate 100 and the light reflection layer 700. The light compensation layer 600 may include a second circular polarization layer including a second circular polarizer. The second circular polarization layer may include a second retarder and/or a second polarizer. The second retarder may include a λ/4 retarder.

The display device 1 may a mirror-display device. Among light incident on the display device 1, light passing through the opening area OPA may be reflected by the light reflection layer 700, and the reflected light may be emitted to the outside through the opening area OPA. When the light compensation layer 600 is omitted, light incident to the display device 1 may pass through the anti-reflection layer 500 to be circularly polarized. In addition, the circularly polarized light may be reflected by the light reflection layer 700. Light reflected by the light reflection layer 700 may be circularly polarized again in the anti-reflection layer 500 and may not be emitted to the outside of the display device 1. In the present embodiments, because the light compensation layer 600 circularly polarizes the circularly polarized light again, the circularly polarized light in each of the anti-reflection layer 500 and the light compensation layer 600 may be emitted to the outside of the display device 1. Accordingly, the display device 1 may function as a mirror-display device.

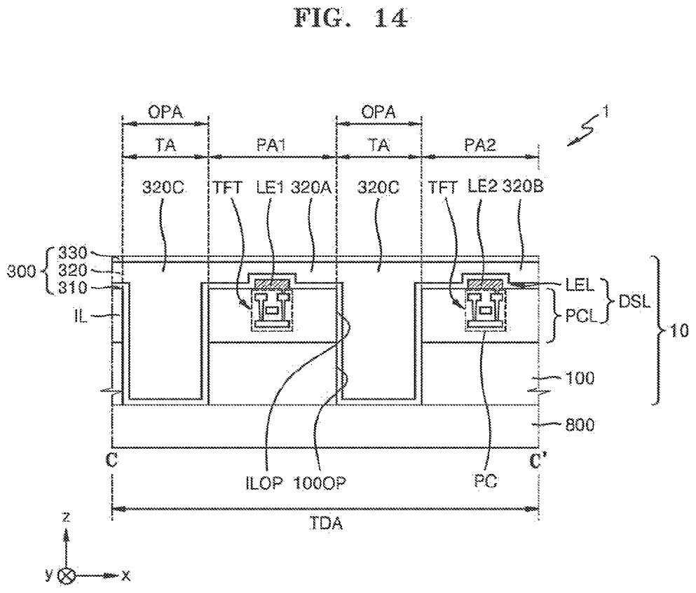

FIG. 14 is a cross-sectional view schematically illustrating the display device 1 taken along the line C-C′ of FIG. 11, according to one or more other embodiments. In FIG. 14, the same reference numerals as those in FIG. 12 refer to the same members/components, and redundant descriptions thereof will be omitted.

Referring to FIG. 14, the display device 1 may include the display panel 10 and a solar cell layer 800. The solar cell layer 800 may be located below the substrate 100. The solar cell layer 800 may include a solar cell. The solar cell may convert energy of light passing through the opening area OPA among light incident to the display device 1 into electrical energy. Accordingly, the solar cell layer 800 may supply electric energy required for the display panel 10. That is, the solar cell layer 800 may function as a battery of the display panel 10. In this case, a battery (not shown) of the display device 1 may be omitted, or an area occupied by the battery may be reduced. When the display panel 10 is a low-power display panel, the battery of the display device 1 may be omitted.

As described above, in a display device according to one or more embodiments of the present disclosure, a substrate may include a first pixel area, a second pixel area, and an opening area arranged between the first pixel area and the second pixel area and having a substrate opening portion, and a first inorganic encapsulation layer may extend from the first pixel area to the second pixel area across the substrate opening portion. Accordingly, the light transmittance or sound transmittance of the display device may be increased between the first pixel area and the second pixel area.

In a method of manufacturing a display device according to one or more embodiments of the present disclosure, an opening area having a substrate opening portion exposing at least a portion of an upper surface of a support substrate may be formed between the first pixel area and the second pixel area. Accordingly, the light transmittance or sound transmittance of the display device may be increased between the first pixel area and the second pixel area.

It should be understood that embodiments described herein should be considered in a descriptive sense only and not for purposes of limitation. Descriptions of features or aspects within the embodiments should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof the be included therein.

What is claimed is:

1. A display device comprising:
a substrate comprising a transmissive display area comprising a first pixel area, a second pixel area, and an opening area between the first pixel area and the second pixel area and defining a substrate opening portion;
a light-emitting element layer above the substrate and comprising a first light-emitting element in the first pixel area and a second light-emitting element in the second pixel area; and
a first inorganic encapsulation layer above the light-emitting element layer and extending from the first pixel area to the second pixel area across the substrate opening portion.

2. The display device of claim 1, further comprising:
an organic encapsulation layer above the first inorganic encapsulation layer and comprising:
a first organic encapsulation portion overlapping the first light-emitting element in a plan view;
a second organic encapsulation portion overlapping the second light-emitting element in the plan view; and
a third organic encapsulation portion overlapping the substrate opening portion in the plan view and extending between the first light-emitting element and the second light-emitting element; and
a second inorganic encapsulation layer above the organic encapsulation layer.

3. The display device of claim 2, wherein the first organic encapsulation portion, the second organic encapsulation portion, and the third organic encapsulation portion are integrally provided.

4. The display device of claim 1, further comprising:
an inorganic insulating layer between the substrate and the light-emitting element layer, defining an inorganic insulating layer opening portion overlapping the substrate opening portion in a plan view, and directly contacting the first inorganic encapsulation layer; and
an organic insulating layer between the inorganic insulating layer and the light-emitting element layer and defining an organic insulating layer opening portion overlapping the substrate opening portion in the plan view, a width of the organic insulating layer opening portion being greater than a width of the inorganic insulating layer opening portion.

5. The display device of claim 4, further comprising:
an organic encapsulation layer above the first inorganic encapsulation layer and having at least a portion in the inorganic insulating layer opening portion and the organic insulating layer opening portion; and
a second inorganic encapsulation layer above the organic encapsulation layer.

6. The display device of claim 4, further comprising an inorganic layer between the organic insulating layer and the light-emitting element layer, defining an inorganic layer opening portion overlapping the substrate opening portion in the plan view, and having at least a portion of a lower surface thereof in direct contact with the first inorganic encapsulation layer, the lower surface facing the substrate.

7. The display device of claim 1, wherein the substrate comprises:
an organic substrate layer defining an organic substrate opening portion as part of the substrate opening portion; and
an inorganic substrate layer above the organic substrate layer and defining an inorganic substrate opening portion as part of the substrate opening portion,
wherein a width of the organic substrate opening portion is greater than a width of the inorganic substrate opening portion, and
wherein the first inorganic encapsulation layer is in direct contact with at least a portion of a lower surface of the inorganic substrate layer, the lower surface facing the organic substrate layer.

8. The display device of claim 1, wherein the light-emitting element layer comprises:
a first pixel electrode in the first pixel area;
a first emission layer above the first pixel electrode;
a second pixel electrode in the second pixel area;
a second emission layer above the second pixel electrode; and
an opposite electrode above the first emission layer and the second emission layer and defining an opposite electrode opening portion overlapping the substrate opening portion in a plan view.

9. The display device of claim 8, wherein the light-emitting element layer further comprises:
a first functional layer between the first pixel electrode and the first emission layer and defining a first functional layer opening portion overlapping the substrate opening portion in the plan view;
a second functional layer between the first emission layer and the opposite electrode and defining a second functional layer opening portion overlapping the substrate opening portion in the plan view; and
a capping layer above the opposite electrode and defining a capping layer opening portion overlapping the substrate opening portion in the plan view.

10. The display device of claim 1, further comprising a protective layer below the substrate, overlapping the opening area in a plan view, and comprising at least one of glass, an organic protective layer comprising an organic material, and an inorganic protective layer comprising an inorganic material.

11. The display device of claim 1, further comprising a component overlapping the first pixel area, the opening area, and the second pixel area in a plan view.

12. The display device of claim 11, wherein the substrate further comprises a display area surrounding at least a portion of the transmissive display area, and
wherein the light-emitting element layer further comprises a third light-emitting element in the display area.

13. The display device of claim 11, wherein the opening area comprises a plurality of opening areas in the transmissive display area, the plurality of opening areas comprising
first opening areas spaced apart from one another along a virtual first straight line extending in a first direction; and
second opening areas spaced apart from one another along a virtual second straight line parallel to the virtual first straight line,
wherein a virtual third straight line that is between adjacent ones of the first opening areas, and that extends in a second direction crossing the first direction, passes through a center of one of the second opening areas.

14. The display device of claim 1, further comprising:
an anti-reflection layer above the first inorganic encapsulation layer and comprising a first circular polarization layer;
a light reflection layer below the substrate; and
a light compensation layer between the substrate and the light reflection layer and comprising a second circular polarization layer.

15. The display device of claim 1, further comprising a solar cell layer below the substrate.

16. A method of manufacturing a display device, the method comprising:
forming a substrate and a display substrate above a support substrate, the substrate comprising a first pixel area, a second pixel area, and a middle area between the first pixel area and the second pixel area, and the display substrate comprising a first pixel electrode in the first pixel area and a second pixel electrode in the second pixel area;
forming an opening area defining a substrate opening portion exposing at least a portion of an upper surface of the support substrate by removing at least a portion of the substrate from the middle area;
forming a first emission layer above the first pixel electrode, a second emission layer above the second pixel electrode, an opposite electrode above the first emission layer and the second emission layer, and a capping layer above the opposite electrode;
forming a first inorganic encapsulation layer above the capping layer and extending from the first pixel area to the second pixel area across the substrate opening portion; and
separating the substrate from the support substrate.

17. The method of claim 16, further comprising:
forming, above the first inorganic encapsulation layer, an organic encapsulation layer comprising a first organic encapsulation portion overlapping the first pixel area in a plan view, a second organic encapsulation portion overlapping the second pixel area in the plan view, and a third organic encapsulation portion overlapping the substrate opening portion in the plan view and extending between the first pixel electrode and the second pixel electrode; and
forming a second inorganic encapsulation layer above the organic encapsulation layer,
wherein the first inorganic encapsulation layer continuously extends across the first pixel area, the opening area, and the second pixel area.

18. The method of claim 16, wherein the substrate comprises an organic substrate layer, and an inorganic substrate layer above the organic substrate layer, and defining an inorganic substrate opening portion overlapping the middle area in a plan view, and
wherein the forming of the opening area comprises forming an organic substrate opening portion having a width that is greater than a width of the inorganic substrate opening portion in the organic substrate layer.

19. The method of claim 16, wherein the forming of the opposite electrode and the capping layer comprises forming a portion of the opposite electrode and a portion of the capping layer above the upper surface of the support substrate, the upper surface being exposed by the substrate opening portion,
wherein the forming of the first inorganic encapsulation layer comprises forming the first inorganic encapsulation layer above the portion of the capping layer in the opening area, and
wherein the separating of the substrate from the support substrate comprises separating the portion of the first inorganic encapsulation layer and the portion of the capping layer from each other in the opening area when the substrate is separated from the support substrate.

20. The method of claim 16, wherein the forming of the opening area comprises:
forming an etch protection layer above the first pixel electrode and the second pixel electrode, the etch protection layer defining an etch protection layer opening portion overlapping the middle area in a plan view in the etch protection layer;
etching at least a portion of the substrate in the middle area; and
removing the etch protection layer.
